(19) United States
(12) Patent Application Publication
(10) Pub. No.: US 2026/0313948 A1
(43) Pub. Date: Oct. 8, 2026

(54) INTEGRATED CIRCUIT DEVICE AND METHOD OF MANUFACTURING THE SAME

(71) Applicant: SAMSUNG ELECTRONICS CO., LTD., Suwon-si (KR)

(72) Inventors: Soyeong AHN, Suwon-si (KR); Suk YANG, Suwon-si (KR); Sangmoon LEE, Suwon-si (KR)

(73) Assignee: SAMSUNG ELECTRONICS CO., LTD., Suwon-si (KR)

(21) Appl. No.: 19/571,748

(22) Filed: Mar. 19, 2026

(30) Foreign Application Priority Data
Apr. 4, 2025 (KR) 10-2025-0044276

(51) Int. Cl. H10D 30/62; H10D 62/10; H10D 86/00

(52) U.S. Cl. CPC H10D 30/6217; H10D 62/117; H10D 86/215

(57) ABSTRACT

An integrated circuit device includes a plurality of channel layers extending in a first horizontal direction and including a first channel layer and a second channel layer, a gate line surrounding the plurality of channel layers, wherein the gate line includes a first sub-gate arranged between the first channel layer and the second channel layer, a source/drain pattern arranged on a sidewall of the gate line, and a channel passivation layer including a first passivation layer and a second passivation layer, wherein the first passivation layer is disposed between the first sub-gate and the first channel layer, and the second passivation layer is arranged between the first sub-gate and the second channel layer. The plurality of channel layers protrude in the first horizontal direction from the sidewall of the gate line, and the plurality of channel layers include transition metal dichalcogenides (TMD).

### CROSS-REFERENCE TO RELATED APPLICATION

This application is based on and claims priority under 35 U.S.C. § 119 to Korean Patent Application No. 10-2025-0044276, filed on Apr. 4, 2025, in the Korean Intellectual Property Office, the disclosure of which is incorporated by reference herein in its entirety.

### BACKGROUND

The inventive concept relates to an integrated circuit device, and more particularly, to an integrated circuit device including a nanosheet field-effect transistor (FET).

Due to the development of electronic technology, down-scaling of integrated circuit devices is rapidly progressing. Accordingly, it is necessary to secure operational accuracy by minimizing leakage current while maintaining the fast operating speeds of integrated circuit devices. Accordingly, various studies are being conducted to provide integrated circuit devices with structures enabling a reduction in leakage current and improved reliability.

### SUMMARY

The inventive concept relates to an integrated circuit device including transition metal dichalcogenides (TMD), in which mobility of charge carriers is improved by a channel layer having a single-crystal structure, and quality of a plurality of channel layers is improved.

The technical problems of the inventive concept are not limited to the technical problems mentioned above, and other technical problems not mentioned will be clearly understood by those skilled in the art from the description below.

According to an aspect of the inventive concept, there is provided an integrated circuit device including a plurality of channel layers extending in a first horizontal direction and including a first channel layer and a second channel layer, a gate line extending in a second horizontal direction intersecting the first horizontal direction and surrounding the plurality of channel layers, wherein the gate line includes a first sub-gate arranged between the first channel layer and the second channel layer, a source/drain pattern arranged on a sidewall of the gate line and connected to the plurality of channel layers, and a channel passivation layer including a first passivation layer and a second passivation layer, wherein the first passivation layer is disposed between the first sub-gate and the first channel layer, and the second passivation layer is arranged between the first sub-gate and the second channel layer. The plurality of channel layers protrude in the first horizontal direction from the sidewall of the gate line, and the plurality of channel layers include transition metal dichalcogenides (TMD).

According to another aspect of the inventive concept, there is provided an integrated circuit device including a plurality of channel layers extending in a first horizontal direction and including a first channel layer and a second channel layer, a gate line extending in a second horizontal direction intersecting the first horizontal direction and surrounding the plurality of channel layers, wherein the gate line includes a first sub-gate arranged between the first channel layer and the second channel layer, and a second sub-gate disposed on an opposite side to the first sub-gate with respect to the first channel layer, a source/drain pattern disposed on a sidewall of the gate line and connected to the plurality of channel layers, a channel passivation layer including a first passivation layer and a second passivation layer, wherein the first passivation layer is disposed between the first sub-gate and the first channel layer, and the second passivation layer is arranged between the first sub-gate and the second channel layer, an insulating spacer disposed between a sidewall of the gate line and the source/drain pattern, and a gate dielectric layer surrounding the first sub-gate. The plurality of channel layers protrude in the first horizontal direction from the insulating spacer. A channel passivation layer is not disposed between the first channel layer and the second sub-gate. The first passivation layer is disposed between the gate dielectric layer and the first channel layer and the gate dielectric layer is in direct contact with the first passivation layer. The plurality of channel layers include transition metal dichalcogenides (TMD).

According to another aspect of the inventive concept, there is provided an integrated circuit device including a plurality of channel layers extending in a first horizontal direction and including a first channel layer and a second channel layer, a gate line extending in a second horizontal direction intersecting the first horizontal direction and surrounding the plurality of channel layers, wherein the gate line includes a first sub-gate disposed between the first channel layer and the second channel layer, and a second sub-gate disposed on an opposite side to the first sub-gate with respect to the first channel layer, a source/drain pattern disposed on a sidewall of the gate line and connected to the plurality of channel layers, a channel passivation layer including a first passivation layer and a second passivation layer, wherein the first passivation layer is disposed between the first sub-gate and the first channel layer, and the second passivation layer is disposed between the first sub-gate and the second channel layer, an insulating spacer disposed between a sidewall of the gate line and the source/drain pattern, and a gate dielectric layer surrounding the first sub-gate. The plurality of channel layers protrude in the first horizontal direction from the insulating spacer. A channel passivation layer is not disposed between the first channel layer and the second sub-gate. The first passivation layer is disposed between the gate dielectric layer and the first channel layer and the gate dielectric layer is in direct contact with the first passivation layer. The plurality of channel layers include transition metal dichalcogenides (TMD). The plurality of channel layers include an even number of channel layers. A thickness in a third direction of each of the plurality of channel layers is substantially the same and the third direction is perpendicular to the first horizontal direction and the second horizontal direction. The plurality of channel layers have a single-crystal structure. The source/drain pattern includes a metal, a semi-metal, a metal oxide, or a combination thereof. The channel passivation layer includes at least one of thiol or S. The channel passivation layer includes trifluoromethanesulfonylimide (TFSI). A thickness in the third direction of each of the plurality of channel layers is in a range of 0.3 nanometers (nm) to 2.0 nm, and a thickness in the third direction of the channel passivation layer is in a range of 0.1 nm to 0.5 nm.

According to another aspect of the inventive concept, there is provided an integrated circuit device manufacturing method including alternately stacking a first sacrificial layer and a second sacrificial layer, forming a first opening through at least part of the first sacrificial layer and the second sacrificial layer, selectively removing part of the second sacrificial layer exposed by the first opening to form a second opening, forming a channel structure on a surface of the first sacrificial layer exposed by the second opening, forming a channel passivation structure, forming a third sacrificial layer to fill the first opening and the second opening, forming a channel passivation layer from the channel passivation structure, forming a plurality of channel layers from the channel structure, and forming a source/drain space, removing part of the first sacrificial layer and the third sacrificial layer to form a dummy gate structure, and forming an insulating spacer on a sidewall of the dummy gate structure.

According to another aspect of the inventive concept, there is provided an integrated circuit device manufacturing method, in which the first sacrificial layer and the second sacrificial layer include materials having different nucleation rates for TMD, the first sacrificial layer includes at least one material among aluminum oxide (AlOₓ), zirconium oxide (ZrOₓ), titanium oxide (TiOₓ), and aluminum oxide (AlOₓ), and the second sacrificial layer includes at least one material among silicon nitride (SiNₓ) and silicon oxide (SiOₓ).

According to another aspect of the inventive concept, there is provided an integrated circuit device manufacturing method, in which the channel structure includes TMD having a single-crystal structure.

According to another aspect of the inventive concept, there is provided an integrated circuit device manufacturing method, in which the channel structure is formed on top and bottom surfaces of the first sacrificial layer.

According to another aspect of the inventive concept, there is provided an integrated circuit device manufacturing method, in which the channel passivation structure includes at least one of thiol or sulfur(S) and the channel passivation structure includes TFSI.

According to another aspect of the inventive concept, there is provided an integrated circuit device manufacturing method, in which, in the forming of the insulating spacer, the channel passivation layers and the plurality of channel layers laterally protrude from the insulating spacer.

According to another aspect of the inventive concept, there is provided an integrated circuit device manufacturing method, in which the channel passivation layers are alternately disposed between the plurality of channel layers and the plurality of channel layers include an even number of channel layers.

According to another aspect of the inventive concept, there is provided an integrated circuit device manufacturing method, in which the channel passivation layer includes a plurality of passivation layers, the plurality of passivation layers are disposed between the first sacrificial layer and the plurality of channel layers, and the plurality of passivation layers are not disposed between the third sacrificial layer and the plurality of channel layers.

According to another aspect of the inventive concept, there is provided an integrated circuit device manufacturing method further including forming an insulating layer in the source/drain space, forming a gate dielectric layer and a gate line, and removing the insulating layer to form a plurality of source/drain patterns. In the removing of the insulating layer, part of both ends of the channel passivation layer is removed.

According to another aspect of the inventive concept, there is provided an integrated circuit device manufacturing method, in which, in the removing of the insulating layer, part of both ends of the channel passivation layer is removed so that both ends of the channel passivation layer extend to a surface formed by a second surface of the insulating spacer, a first surface of the insulating spacer faces the gate line, and the second surface of the insulating spacer is opposite to the first surface of the insulating spacer.

### BRIEF DESCRIPTION OF THE DRAWINGS

Embodiments will be more clearly understood from the following detailed description taken in conjunction with the accompanying drawings in which:

FIG. 1 is a planar layout diagram of some components of an integrated circuit device according to embodiments;

FIG. 2A is a cross-sectional view illustrating a partial configuration of a cross-section taken along the line X1-X1′ of FIG. 1;

FIG. 2B is an enlarged cross-sectional view of some components included in FIG. 2A;

FIG. 3 is a cross-sectional view illustrating a partial configuration of a cross-section taken along the line Y1-Y2′ of FIG. 1;

FIG. 4 is a cross-sectional view illustrating a partial configuration of a cross-section taken along the line Y2-Y2′ of FIG. 1;

FIG. 5A is a cross-sectional view illustrating a partial configuration of an integrated circuit device according to embodiments;

FIG. 5B is an enlarged cross-sectional view of some components included in FIG. 5A;

FIG. 6A is a cross-sectional view illustrating a partial configuration of an integrated circuit device according to embodiments;

FIG. 6B is an enlarged cross-sectional view of some components included in FIG. 6A;

FIG. 7 is a cross-sectional view illustrating a partial configuration of an integrated circuit device according to embodiments;

FIG. 8 is a flowchart illustrating an integrated circuit device manufacturing method according to embodiments; and

FIGS. 9A-9N are views for sequentially describing an integrated circuit device manufacturing method according to embodiments.

### DETAILED DESCRIPTION OF THE EMBODIMENTS

Hereinafter, embodiments of the inventive concept will be described in detail with reference to the accompanying drawings.

Embodiments of the inventive concept are provided to more completely explain the inventive concept to those skilled in the art, the following embodiments may be modified in various different forms, and the scope of the inventive concept is not limited to the following embodiments. The embodiments are provided so that the inventive concept will be more thorough and complete, and will fully convey the spirit of the inventive concept to those skilled in the art. In addition, the thickness and size of each layer in the drawing are exaggerated for convenience and clarity of explanation.

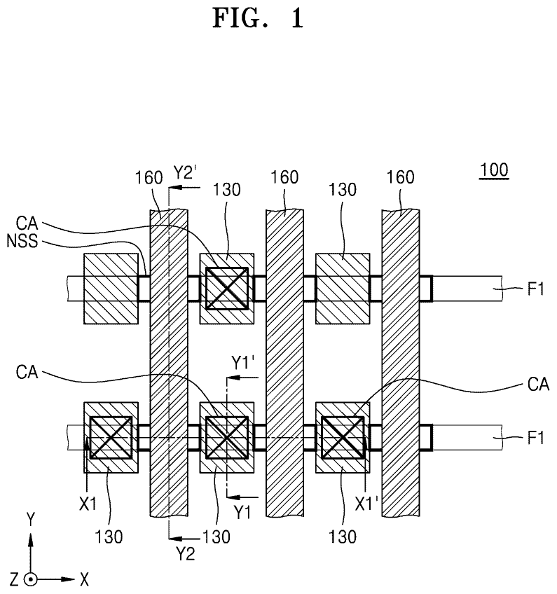

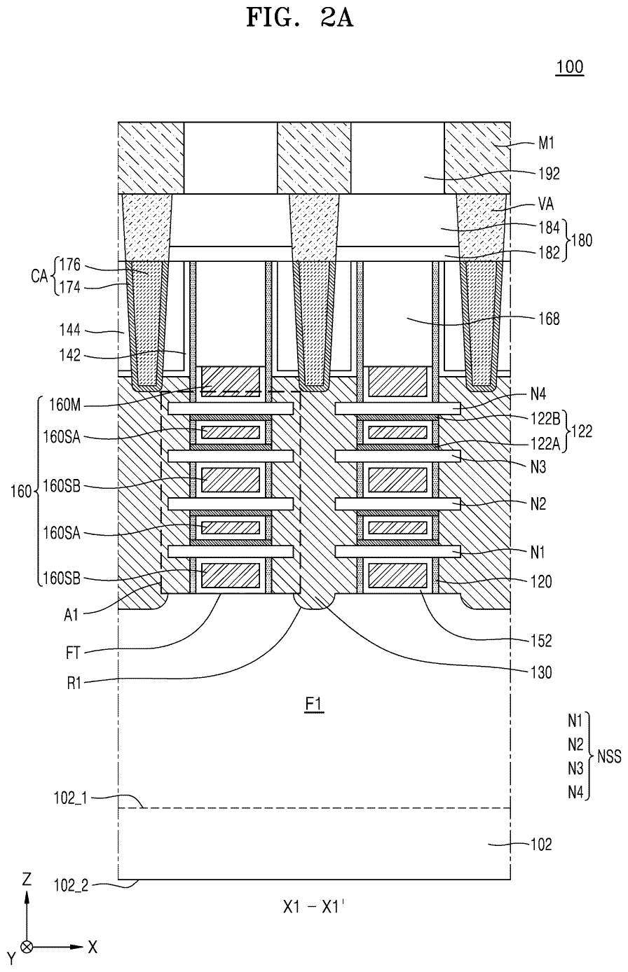

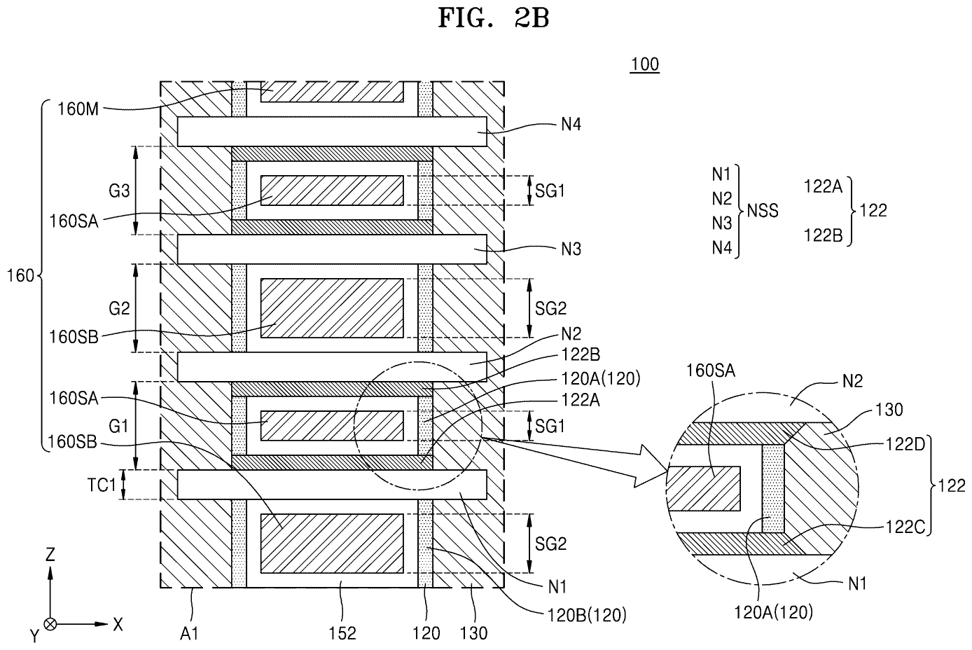

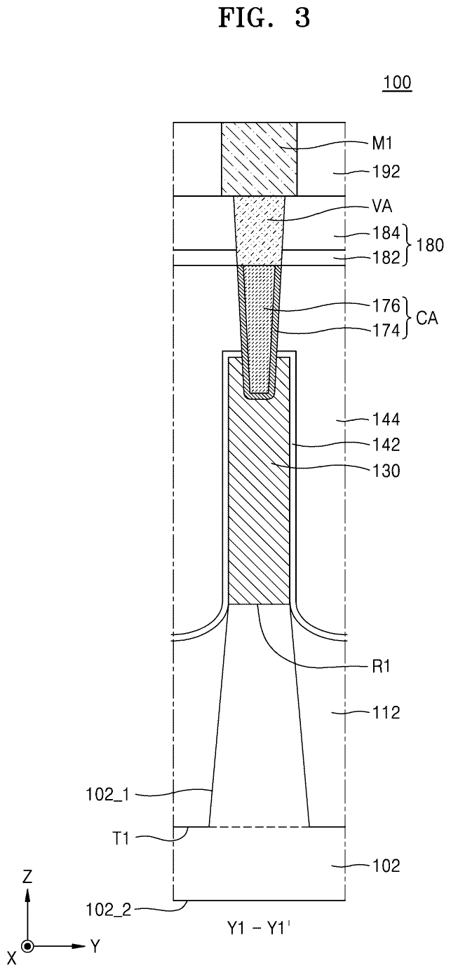

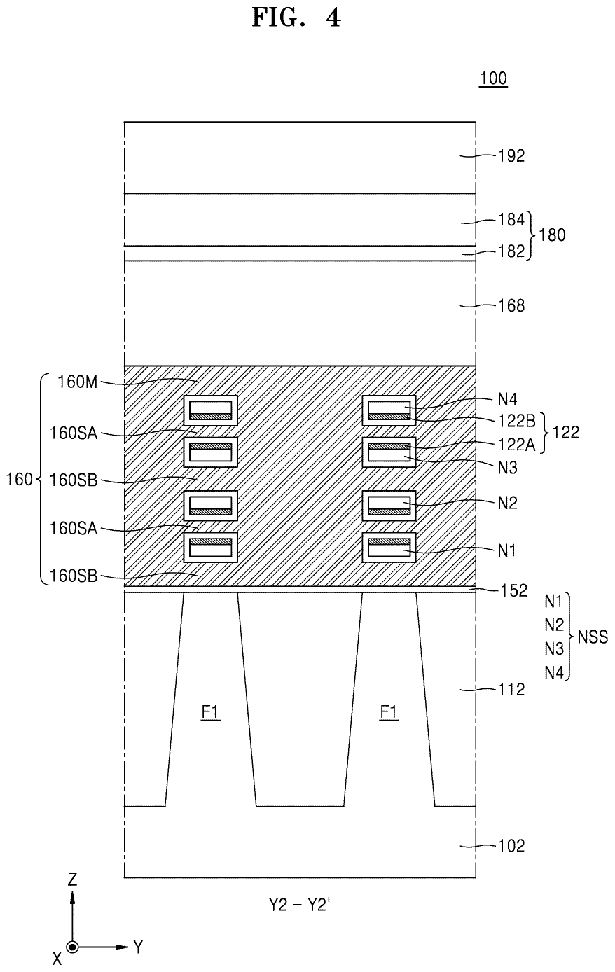

FIG. 1 is a planar layout diagram of some components of an integrated circuit device 100 according to embodiments. FIG. 2A is a cross-sectional view illustrating a partial configuration of a cross-section taken along the line X1-X1′ of FIG. 1. FIG. 2B is an enlarged cross-sectional view of some components included in FIG. 2A. FIG. 3 is a cross-sectional view illustrating a partial configuration of a cross-section taken along the line Y1-Y2′ of FIG. 1. FIG. 4 is a cross-sectional view illustrating a partial configuration of a cross-section taken along the line Y2-Y2′ of FIG. 1. More specifically, FIG. 2B is an enlarged cross-sectional view of the first portion A1 of FIG. 2A.

Referring to FIGS. 1 to 4, the integrated circuit device 100 including a nanowire or nanosheet-shaped active region and a field effect transistor (FET) having a gate-all-around structure including a gate surrounding the active region will be described. For example, the integrated circuit device 100 may include a multi-bridge channel FET (MBCFET) device. However, the inventive concept is not limited thereto, and the integrated circuit device 100 may include a planar FET device or a finFET device.

In embodiments, the integrated circuit device 100 of the inventive concept may include a plurality of active regions F1 protruding from a substrate 102 to define trench regions T1 on a substrate 102. The plurality of active regions F1 may extend in parallel to one another in a first horizontal direction (X direction) on the substrate 102 and may be spaced apart from one another in a second horizontal direction (Y direction).

The substrate 102 may include a first surface 102_1 and a second surface 102_2 opposite to the first surface 102_1. The plurality of active regions F1 may extend in the first horizontal direction (X direction) on the first surface 102_1 of the substrate 102.

In embodiments, the substrate 102 may include a semiconductor such as silicon (Si) or germanium (Ge), or a compound semiconductor such as SiGe, SiC, GaAs, InAs, InGaAs, or InP. The terms “SiGe”, “SiC”, “GaAs”, “InAs”, “InGaAs”, and “InP” used in the current specification refer to materials including elements included in each term, and are not chemical formulas representing stoichiometric relationships. The substrate 102 may include a conductive region, for example, an impurity-doped well, or an impurity-doped structure.

In embodiments, a device isolation layer 112 may be arranged in the trench region T1 defining the active region F1. The device isolation layer 112 may cover part of a sidewall of the active region F1 in the trench region T1 and may be spaced apart from the substrate 102 in a vertical direction (Z direction). The device isolation layer 112 may include a silicon oxide layer.

In embodiments, a plurality of gate lines 160 may be arranged on the active region F1. Each of the plurality of gate lines 160 may extend in the second horizontal direction (Y direction). A plurality of nanosheet stacks NSS may be arranged on a fin top surface FT of the active region F1 in regions in which the active region F1 and the plurality of gate lines 160 intersect. Each of the plurality of nanosheet stacks NSS may include at least one nanosheet facing the fin top surface FT at a position apart from the fin top surface FT of the active region F1 in the vertical direction (Z direction). The term “nanosheet” used in the current specification refers to a conductive structure having a cross-section substantially perpendicular to a direction in which current flows. The nanosheet should be understood as including nanowires.

The gate line 160 may include a main gate 160M and first and second sub-gates 160SA and 160SB. The main gate 160M may cover a top surface of the nanosheet stack NSS and may extend in the second horizontal direction (Y direction). The first and second sub-gates 160SA and 160SB may be integrally connected to the main gate 160M, and may be arranged among first to fourth channel layers N1, N2, N3, and N4, respectively, and between the active region F1 and a first channel layer N1.

The first sub-gates 160SA may be arranged in parts among the first to fourth channel layers N1, N2, N3, and N4. In embodiments, the first sub-gates 160SA may be provided among the first to fourth channel layers N1, N2, N3, and N4, in which a channel passivation layer 122 is provided, among the first to fourth channel layers N1, N2, N3, and N4. The second sub-gates 160SB may be provided among the first to fourth channel layers N1, N2, N3, and N4, in which the channel passivation layer 122 is not provided, among the first to fourth channel layers N1, N2, N3, and N4.

In embodiments, a first sub-gate thickness SG1 that is a thickness in the vertical direction of the first sub-gate 160SA may be less than a second sub-gate thickness SG2 that is a thickness in the vertical direction of the second sub-gate 160SB.

The gate line 160 may include a metal, metal nitride, metal carbide, or a combination thereof. The metal may be selected from titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from TiN and TaN. The metal carbide may include TiAlC. In embodiments, the gate line 160 may have a structure in which a metal nitride layer, a metal layer, a conductive capping layer, and a gap-fill metal layer are sequentially stacked. The metal nitride layer and the metal layer may include at least one metal selected from Ti, tantalum (Ta), W, Ru, Nb, Mo, and Hf. The gap-fill metal layer may include a W layer or an aluminum (Al) layer. The plurality of gate lines 160 may include at least one work function metal-containing layer. The at least one work function metal-containing layer may include at least one metal selected from Ti, W, Ru, Nb, Mo, Hf, Ni, Co, Pt, Yb, Tb, Dy, Er, and Pd. In some embodiments, the gate line 160 may include a stacked structure of TiAlC/TiN/W, a stacked structure of TiN/TaN/TiAlC/TiN/W, or a stacked structure of TiN/TaN/TiN/TiAlC/TiN/W. However, the inventive concept is not limited thereto.

In embodiments, each of the plurality of nanosheet stacks NSS may include the first to fourth channel layers N1, N2, N3, and N4 overlapping one another in the vertical direction (Z direction) on the active region F1. Vertical distances (Z direction) from the fin top surface FT of the active region F1 to the first to fourth channel layers N1, N2, N3, and N4 may be different. Each of the plurality of gate lines 160 may surround the channel layer included in the nanosheet stack NSS overlapping in the vertical direction (Z direction).

The number of channel layers included in the nanosheet stack NSS is not limited thereto.

Although it is illustrated in FIG. 1 that a planar shape of the nanosheet stack NSS is approximately square, the inventive concept is not limited thereto. The nanosheet stack NSS may have various planar shapes according to a planar shape of each of the active region F1 and the gate line 160. In the current example, the plurality of nanosheet stacks NSS and the plurality of gate lines 160 are arranged on one active region F1, and the plurality of nanosheet stacks NSS are arranged in a line in the first horizontal direction (X direction) on one active region F1. However, the number of nanosheet stacks NSS and gate lines 160 arranged on one active region F1 is not particularly limited.

In embodiments, a channel thickness TC1 that is a thickness in the vertical direction of each of the first to fourth channel layers N1, N2, N3, and N4 included in the nanosheet stack NSS may have a thickness selected in a range of about 0.3 nanometers (nm) to about 2.0 nm. For example, the channel thickness TC1 may have a thickness selected in a range of about 0.2 nm to about 3.0 nm. However, the inventive concept is not limited thereto. At this time, the thickness of each of the first to fourth channel layers N1, N2, N3, and N4 refers to a size in the vertical direction (Z direction). In embodiments, the first to fourth channel layers N1, N2, N3, and N4 may have substantially the same thickness in the vertical direction (Z direction). Each of the first channel layer N1, the second channel layer N2, the third channel layer N3, and the fourth channel layer N4 may have a generally uniform thickness with respect to the area of each channel layer.

As used herein, the expression “substantially the same” may refer to having the same value relative to other value(s) compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

In embodiments, the first to fourth channel layers N1, N2, N3, and N4 included in one nanosheet stack NSS may have substantially the same size in the first horizontal direction (X direction). Although it is illustrated in FIG. 2A that each of the plurality of nanosheet stacks NSS includes four channel layers, the inventive concept is not limited thereto. For example, due to a method 1000 of manufacturing an integrated circuit device described below, the nanosheet stack NSS may include at least two channel layers, or the number of channel layers constituting the nanosheet stack NSS may be an even number. For example, the number of channel layers constituting the nanosheet stack NSS may be an even number, such as 2, 4, 6, or more, which is because, in the method 1000 of manufacturing an integrated circuit device described below, the channel layer may be formed in units of two.

In embodiments, the first to fourth channel layers N1, N2, N3, and N4 included in one nanosheet stack NSS may be spaced apart from one another by equal spacing. For example, a first gap G1 that is a distance in the vertical direction between the first channel layer N1 and the second channel layer N2, a second gap G2 that is a distance in the vertical direction between the second channel layer N2 and the third channel layer N3, and a third gap G3 that is a distance in the vertical direction between the third channel layer N3 and the fourth channel layer N4 may be substantially the same.

In embodiments, the first to fourth channel layers N1, N2, N3, and N4 may include a two-dimensional semiconductor material. At this time, the two-dimensional material may refer to a material having a layered structure in which constituent atoms are two-dimensionally bonded. Two-dimensional materials with semiconductor properties have excellent electrical properties and may maintain high mobility without significantly changing their properties even when the thickness is reduced to nano-scale. For example, the first to fourth channel layers N1, N2, N3, and N4 may include transition metal dichalcogenides (TMD). In other embodiments, the first to fourth channel layers N1, N2, N3, and N4 may include graphene.

In embodiments, TMD as a two-dimensional material with semiconductor properties may refer to a compound of a transition metal and a chalcogen element. At this time, the transition metal may include, for example, at least one of Mo, W, Nb, vanadium (V), Ta, Ti, zirconium (Zr), Hf, Co, technetium (Tc), or rhenium (Re), and the chalcogen element may include, for example, at least one of sulfur(S), selenium (Se), or tellurium (Te). As a specific example, the TMD may include MoS₂, MoSe₂, MoTe₂, WS₂, WSe₂, WTe₂, ZrS₂, ZrSe₂, HfS₂, HfSe₂, NbSe₂, and ReSe₂. However, the inventive concept is not limited thereto.

In embodiments, each of the first to fourth channel layers N1, N2, N3, and N4 included in the nanosheet stack NSS may include a single crystal TMD. For example, each of the first to fourth channel layers N1, N2, N3, and N4 included in the nanosheet stack NSS may include single crystal MoS₂, WS₂, or WSe₂.

Unlike polycrystalline TMD, single-crystal TMD have no grain boundaries, and thus mobility of charge carriers (electrons and holes) in each of the first to fourth channel layers N1, N2, N3, and N4 including single-crystal TMD may be relatively high. Accordingly, performance of an integrated circuit including the first to fourth channel layers N1, N2, N3, and N4 including single-crystal TMD may be higher than performance of an integrated circuit including the first to fourth channel layers N1, N2, N3, and N4 including polycrystalline TMD.

In addition, in the integrated circuit device 100 according to embodiments, the first to fourth channel layers N1, N2, N3, and N4 including a single-crystal TMD are not separately generated and are formed through a single process as described below in an integrated circuit device manufacturing method 1000.

The integrated circuit device 100 according to embodiments may include a channel including a single-crystal TMD having a uniform thickness through a single process, unlike a conventional process in which a deposition process is performed on each channel layer. After the first to fourth channel layers N1, N2, N3, and N4 are formed, the formation of oxide that may occur may be prevented through the channel passivation layer 122 described below, and at the same time, doping of the first to fourth channel layers N1, N2, N3, and N4 may be performed through the channel passivation layer 122.

The first to fourth channel layers N1, N2, N3, and N4 including a single-crystal TMD may be formed through selective area growth in the integrated circuit device manufacturing method 1000 described below, which will be specifically described below. A single-crystal ratio of the first to fourth channel layers N1, N2, N3, and N4 may be, for example, in a range of 95% to 99.9%, or in a range of 99% to 100%. However, the inventive concept is not limited by the numerical ranges.

A channel passivation layer 122 may be disposed on one surface of each of some of the first to fourth channel layers N1, N2, N3, and N4. In embodiments, the channel passivation layer 122 may be provided in part of between two adjacent channel layers of the first to fourth channel layers N1, N2, N3, and N4. In embodiments, channel passivation layers 122 may be provided alternately between two adjacent channel layers of the first to fourth channel layers N1, N2, N3, and N4. For example, the channel passivation layer 122 may be disposed between the first channel layer N1 and the second channel layer N2, the channel passivation layer 122 may not be disposed between the second channel layer N2 and the third channel layer N3, and the channel passivation layer 122 may be disposed between the third channel layer N3 and the fourth channel layer N4.

A first passivation layer 122A may be disposed on one surface of the first channel layer N1. A second passivation layer 122B may be disposed on one surface of the second channel layer N2 adjacent to the first channel layer N1. The first passivation layer 122A and the second passivation layer 122B may be included in the channel passivation layer 122.

The first passivation layer 122A may directly contact a top surface of the first channel layer N1. A length in the first horizontal direction of the first passivation layer 122A may be less than a length in the first horizontal direction of the first channel layer N1. The first passivation layer 122A may overlap the first channel layer N1 in the vertical direction. In embodiments, the entire first passivation layer 122A may overlap the first channel layer N1 in the vertical direction. That is, the first passivation layer 122A may be included in the first channel layer N1 in the first horizontal direction.

The second passivation layer 122B may be in direct contact with a bottom surface of the second channel layer N2. A length in the first horizontal direction of the second passivation layer 122B may be less than a length in the first horizontal direction of the second channel layer N2. The second passivation layer 122B may overlap the second channel layer N2 in the vertical direction. In embodiments, the entire second passivation layer 122B may overlap the second channel layer N2 in the vertical direction. That is, the second passivation layer 122B may be included in the second channel layer N2 in the first horizontal direction.

For example, the channel passivation layer 122 may have a thickness in the vertical direction of 0.1 nm to 0.5 nm. That is, each of the first passivation layer 122A and the second passivation layer 122B may have a thickness in the vertical direction of 0.1 nm to 0.5 nm. For example, the channel passivation layer 122 may have a thickness in the vertical direction of 0.1 nm to 1.0 nm.

The channel passivation layer 122 may include a chemical material including thiol or sulfur. In embodiments, the channel passivation layer 122 may include 3-octanethiol, ethanethiol, and diphenyl sulfide. The channel passivation layer 122 may include trifluoromethanesulfonylimide (TFSI) in addition to 3-octanethiol, ethanethiol, or diphenyl sulfide.

The channel passivation layer 122 having such a material composition may control a charge carrier concentration at each surface of the first to fourth channel layers N1, N2, N3, and N4 including TMD to generate doping effect for the first to fourth channel layers N1, N2, N3, and N4. In addition, oxidation of surfaces of the first to fourth channel layers N1, N2, N3, and N4 that may occur during manufacturing processes may be prevented by the channel passivation layer 122.

Both sidewalls of the gate line 160 may be covered with an insulating spacer 120 on the active region F1. The insulating spacer 120 may cover both sidewalls of the main gate 160M, both sidewalls of each of the plurality of sub-gates 160SA and 160SB, and both sidewalls of the capping insulation pattern 168. The insulating spacer 120 may be spaced apart from the gate line 160 with a gate dielectric layer 152 therebetween. The insulating spacer 120 may include silicon nitride, silicon oxide, SiCN, SiBN, SiON, SiOCN, SiBCN, SiOC, or a combination thereof. The terms “SiCN”, “SiBN”, “SiON”, “SiOCN”, “SiBCN”, and “SiOC” used in the current specification refer to materials including elements included in each term, and are not chemical formulas representing stoichiometric relationships.

The insulating spacer 120 may include a first spacer 120A and a second spacer 120B. Each of the first spacer 120A and the second spacer 120B may be disposed between two adjacent channel layers.

The first spacer 120A may be disposed between the first passivation layer 122A and the second passivation layer 122B. In embodiments, upper and lower ends of the first spacer 120A may be in contact with the first passivation layer 122A and the second passivation layer 122B, respectively.

A first sidewall of the first spacer 120A may face the first sub-gate 160SA, and the gate dielectric layer 152 may be interposed between the first spacer 120A and the first sub-gate 160SA. A second sidewall of the first spacer 120A may be in contact with a source/drain pattern 130. The first sidewall of the first spacer 120A and the second sidewall of the first spacer 120A may be opposite sides to each other.

One side end of the first passivation layer 122A may extend to the second sidewall of the first spacer 120A. Alternatively, as illustrated in the partially enlarged circular view of FIG. 2A, one side end of the first passivation layer 122C may protrude beyond the second sidewall of the first spacer 120A. In other words, one side end of the first passivation layer 122C may extend beyond the second sidewall of the first spacer 120A.

One end of the first passivation layer 122A may extend to the second sidewall of the first spacer 120A, or one end of the first passivation layer 122A may extend beyond the second sidewall of the first spacer 120A so that one end of the first passivation layer 122A may extend to a surface formed by the second sidewall of the first spacer 120A.

As illustrated in the enlarged circular view of a portion of FIG. 2A, the first passivation layer 122C may have a shape in which a width of the first passivation layer 122C is reduced as the first passivation layer 122C is away from the first channel layer N1 in a portion adjacent to the first channel layer N1.

In embodiments, at least part of upper and lower ends of the second spacer 120B may be in contact with the channel layer. The second spacer 120B may be disposed on an opposite side to the first spacer 120A based on the first channel layer N1. For example, the second spacer 120B disposed on an opposite side to the first spacer 120A based on the first channel layer N1 may have an upper end in contact with a bottom surface of the first channel layer N1.

The second spacer 120B disposed between the second channel layer N2 and the third channel layer N3 may have the upper and lower ends in contact with the third channel layer N3 and the second channel layer N2, respectively.

The first sidewall of the second spacer 120B may face the second sub-gate 160SB, and the gate dielectric layer 152 may be between the second spacer 120B and the second sub-gate 160SB. A second sidewall of the second spacer 120B may be in contact with the source/drain pattern 130. The first sidewall of the first spacer 120A and the second sidewall of the first spacer 120A may be opposite sides to each other.

The insulating spacer 120 may be provided as a single body up to the upper portion of the nanosheet stack NSS including the first spacer 120A and the second spacer 120B adjacent to the first to fourth channel layers N1, N2, N3, and N4, the main gate 160M, and the capping insulation pattern 168.

The gate dielectric layer 152 may be between the first to fourth channel layers N1, N2, N3, and N4 and the gate line 160. The gate dielectric layer 152 may include portions covering surfaces of the first to fourth channel layers N1, N2, N3, and N4, portions covering sidewalls of the main gate 160M, portions covering the fin top surface FT of the active region F1, and portions covering a top surface of the device isolation layer 112.

In embodiments, for example, the gate dielectric layer 152 may include a high-k dielectric layer. The high-k dielectric layer may include a material having a higher dielectric constant than a silicon oxide layer. For example, the high-k dielectric layer may have a dielectric constant of about 10 to about 25. The high-k dielectric layer may include hafnium oxide. However, the inventive concept is not limited thereto.

In embodiments, a plurality of source/drain patterns 130 may be arranged among a plurality of gate lines 160, respectively. Each of the plurality of source/drain patterns 130 may be positioned adjacent to at least one gate line 160 selected from the plurality of gate lines 160. Each of the plurality of source/drain patterns 130 may have surfaces facing adjacent channel layers.

Each portion of the first to fourth channel layers N1, N2, N3, and N4 protruding in the first horizontal direction from the sidewall of the insulating spacer 120 may be surrounded by the source/drain pattern 130. For example, sidewalls, a top surface, and a bottom surface of the first channel layer N1 may be surrounded by the source/drain pattern 130 and may be in direct contact with the source/drain pattern 130. Through the portions protruding from the sidewall of the insulating spacer 120 of the first to fourth channel layers N1, N2, N3, and N4, a contact area between the source/drain pattern 130 and the first to fourth channel layers N1, N2, N3, and N4 may be secured.

The source/drain pattern 130 may include a metal material. In embodiments, the source/drain pattern 130 may include a semi-metal material. The semi-metal material may include bismuth (Bi), arsenic (As), and antimony (Sb). However, the inventive concept is not limited thereto. Because the source/drain pattern 130 includes a metal material, ohmic contact may be formed between the first to fourth channel layers N1, N2, N3, and N4 and the source/drain pattern 130. Hereinafter, the source/drain pattern 130 is described as including a metal material.

For example, the source/drain pattern 130 may include an alloy including at least one or a combination of metal materials including Ti, Ni, Pd, gold (Au), Pt, W, Mo, Co, chromium (Cr), and silver (Ag). For example, the source/drain pattern 130 may include a plurality of layers including a metal material.

In embodiments, as illustrated in FIG. 3, the source/drain pattern 130 may have sidewalls extending substantially vertically and a flat top surface, and both sidewalls of the source/drain pattern 130 may be continuously connected to a first surface 102_1 of the substrate 102. However, the shape of the source/drain pattern 130 is not limited thereto.

However, it is not excluded that each of the plurality of source/drain patterns 130 includes an epitaxially grown semiconductor layer. In embodiments, each of the plurality of source/drain patterns 130 may include an epitaxially grown Si layer, an epitaxially grown SiC layer, or a plurality of epitaxially grown SiGe layers. When the source/drain pattern 130 constitutes an n-channel metal-oxide-semiconductor field-effect transistor (MOSFET) (NMOS) transistor, the source/drain pattern 130 may include a Si layer doped with an n-type dopant or a SiC layer doped with an n-type dopant. The n-type dopant may be selected from phosphorus (P), arsenic (As), and antimony (Sb).

In embodiments, a plurality of recesses R1 may be formed in the active region F1. A vertical level of the lowermost surface of each of the plurality of recesses R1 may be lower than a vertical level of the fin top surface FT of the active region F1. Each of the plurality of source/drain patterns 130 may have a complementary shape along the shape formed by the plurality of recesses R1 and the fin top surface FT.

In some embodiments, each of the plurality of source/drain patterns 130 may be in contact with at least part of the plurality of recesses R1 and the fin top surface FT. Each of the plurality of source/drain patterns 130 may have a shape filling each of the plurality of recesses R1. In addition, each of the plurality of source/drain patterns 130 may fill a region between the first to fourth channel layers N1, N2, N3, and N4 protruding from the insulating spacer 120 toward the source/drain pattern 130 and may fill a region between the first channel layer N1 and the active region F1.

In embodiments, an insulating liner 142 and an inter-gate insulating layer 144 may be sequentially arranged on the plurality of source/drain patterns 130. The insulating spacer 120 and the plurality of source/drain patterns 130 may be covered with the insulating liner 142. In embodiments, the insulating liner 142 may include SiN, SiCN, SiBN, SiON, SiOCN, SiBCN, or a combination thereof. However, the inventive concept is not limited thereto. The inter-gate insulating layer 144 may include a silicon oxide layer. However, the inventive concept is not limited thereto.

In embodiments, a plurality of source/drain contacts CA may be arranged on the plurality of source/drain patterns 130. Each of the plurality of source/drain contacts CA may penetrate the insulating liner 142 and the inter-gate insulating layer 144 in the vertical direction (Z direction) and may be electrically connected to at least one source/drain pattern 130 selected from the plurality of source/drain patterns 130. The plurality of source/drain contacts CA may be in contact with the plurality of source/drain patterns 130, respectively.

The plurality of source/drain contacts CA may be electrically connected to the plurality of source/drain patterns 130, respectively. Each of the plurality of source/drain contacts CA may be spaced apart from the main gate 160M of the gate line 160 in the first horizontal direction (X direction) with the first insulating spacer 118 therebetween.

In embodiments, each of the plurality of source/drain contacts CA may include a conductive barrier layer 174 and a contact plug 176. A bottom surface and a sidewall of the contact plug 176 may be covered with the conductive barrier layer 174. The conductive barrier layer 174 may include a metal or conductive metal nitride. For example, the conductive barrier layer 174 may include Ti, Ta, W, TiN, TaN, WN, WCN, TiSiN, TaSiN, WSiN, or a combination thereof. However, the inventive concept is not limited thereto. The contact plug 176 may include Mo, W, Co, Ru, manganese (Mn), Ti, Ta, Al, Cu, a combination thereof, or an alloy thereof. However, the inventive concept is not limited thereto. In some embodiments, the conductive barrier layer 174 may be omitted from each of the plurality of source/drain contacts CA.

In embodiments, a top surface of each of the source/drain contact CA, the capping insulation pattern 168, the insulating liner 142, and the inter-gate insulating layer 144 may be covered with an upper insulating structure 180. The upper insulating structure 180 may include an etch stop layer 182 and an interlayer insulating layer 184 sequentially stacked on each of the plurality of source/drain contacts CA, the plurality of capping insulation patterns 168, and the inter-gate insulating layer 144.

The etch stop layer 182 may include SiC, SiN, nitrogen-doped silicon carbide (SiC:N), SiOC, AlN, AlON, AlO, AlOC, or a combination thereof.

The interlayer insulating layer 184 may include an oxide layer, a nitride layer, an ultra-low k (ULK) layer having an ultra low dielectric constant K of about 2.2 to about 2.4, or a combination thereof. For example, the interlayer insulating layer 184 may include a tetraethylorthosilicate (TEOS) layer, a high-density plasma (HDP) oxide layer, a boro-phospho-silicate glass (BPSG) layer, a flowable chemical vapor deposition (FCVD) oxide layer, a SiON layer, a SiN layer, a SiOC layer, a SiCOH layer, or a combination thereof. However, the inventive concept is not limited thereto.

In embodiments, a plurality of source/drain via contacts VA may be arranged on the plurality of source/drain contacts CA, respectively. Each of the plurality of source/drain via contacts VA may be in contact with the source/drain contact CA through the upper insulating structure 180. Each of the plurality of source/drain patterns 130 may be electrically connected to the source/drain via contact VA through a metal silicide layer 172 and the source/drain contact CA. A bottom surface of each of the plurality of source/drain via contacts VA may be in contact with a top surface of the source/drain contact CA. Each of the plurality of source/drain via contacts VA may include Mo or W. However, the inventive concept is not limited thereto.

In embodiments, a top surface of each of the upper insulating structure 180 and the plurality of source/drain via contacts VA may be covered with an upper insulating layer 192. A constituent material of the upper insulating layer 192 is substantially the same as described above for the constituent material of the interlayer insulating layer 184.

In embodiments, a plurality of upper wiring layers M1 may be arranged through the upper insulating layer 192. Each of the plurality of upper wiring layers M1 may be electrically connected to one source/drain via contact VA selected from the plurality of source/drain via contacts VA thereunder. The plurality of upper wiring layers M1 may include Mo, Cu, W, Co, Ru, Mn, Ti, Ta, Al, a combination thereof, or an alloy thereof. However, the inventive concept is not limited thereto.

In the integrated circuit device 100 according to embodiments, the first to fourth channel layers N1, N2, N3, and N4 of the integrated circuit device may include single-crystal TMD so that mobility of charge carriers in the first to fourth channel layers N1, N2, N3, and N4 may be improved. Because the first to fourth channel layers N1, N2, N3, and N4 are formed by a single process, the first to fourth channel layers N1, N2, N3, and N4 with uniform quality may be formed. In addition, oxidation of the first to fourth channel layers N1, N2, N3, and N4 may be prevented by the channel passivation layer 122. These features may improve performance and quality of the integrated circuit device.

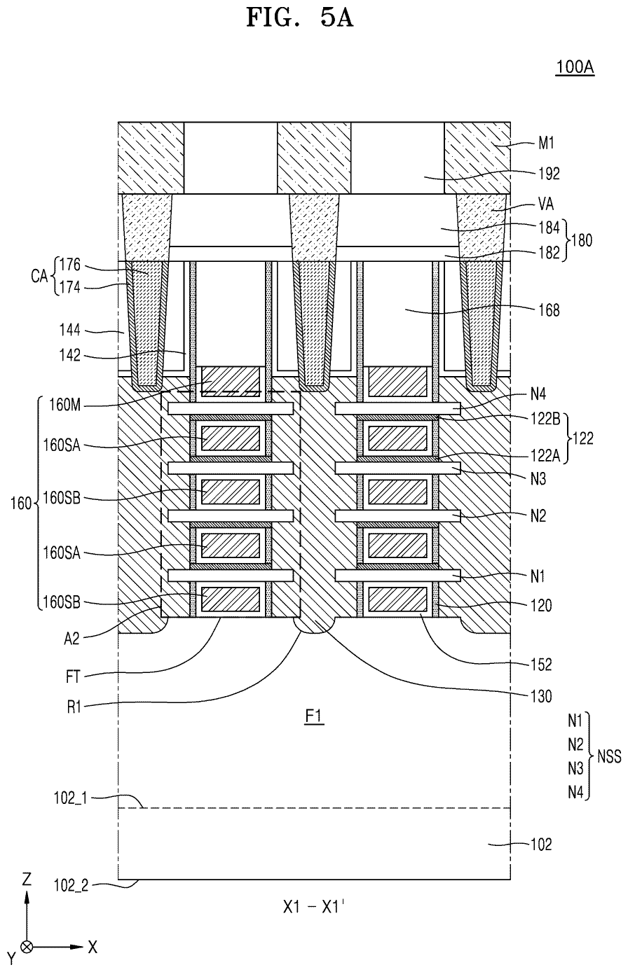

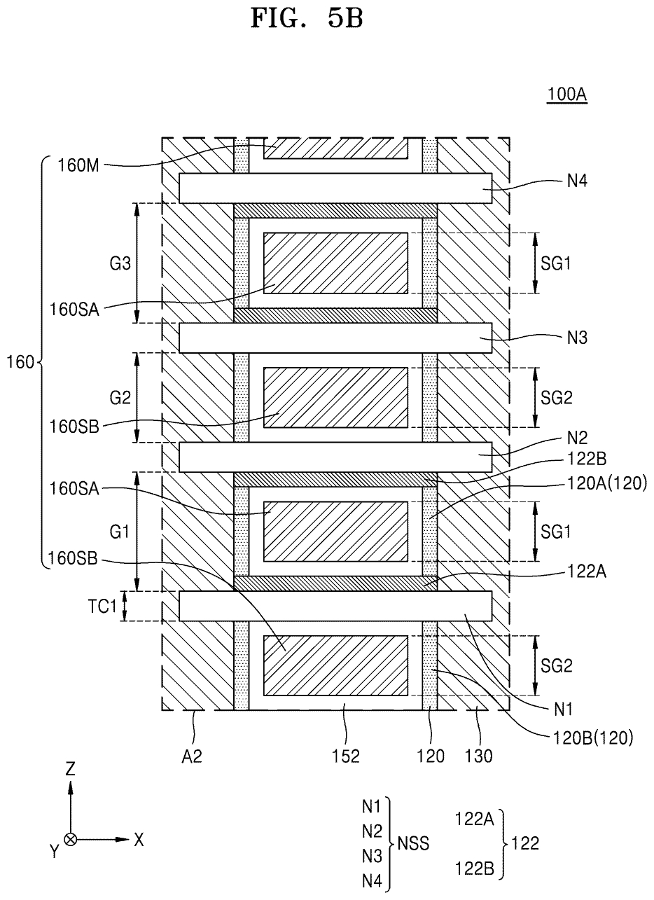

FIG. 5A is a cross-sectional view illustrating a partial configuration of an integrated circuit device 100A according to embodiments. FIG. 5B is an enlarged cross-sectional view of some components included in FIG. 5A. More specifically, FIG. 5B is an enlarged cross-sectional view of the second portion A2 of FIG. 5A. Anything not described below may be substantially identical to what is described above.

Referring to FIGS. 5A and 5B, in the integrated circuit device 100A according to embodiments, a first sub-gate thickness SG1 that is a thickness in the vertical direction of a first sub-gate 160SA may be substantially equal to a second sub-gate thickness SG2 that is a thickness in the vertical direction of a second sub-gate 160SB. The first to fourth channel layers N1, N2, N3, and N4 included in one nanosheet stack NSS may have an alternating spacing between adjacent channel layers.

For example, a first gap G1 that is a distance in the vertical direction between the first channel layer N1 and the second channel layer N2 may be different from a second gap G2 that is a distance in the vertical direction between the second channel layer N2 and the third channel layer N3. The second gap G2 may be different from a third gap G3 that is a distance in the vertical direction between the third channel layer N3 and the fourth channel layer N4. In addition, the first gap G1 may be substantially identical to the third gap G3.

Because the first to fourth channel layers N1, N2, N3, and N4 are formed in a single manufacturing process, the first to fourth channel layers N1, N2, N3, and N4 may have substantially the same thickness in the vertical direction (Z direction).

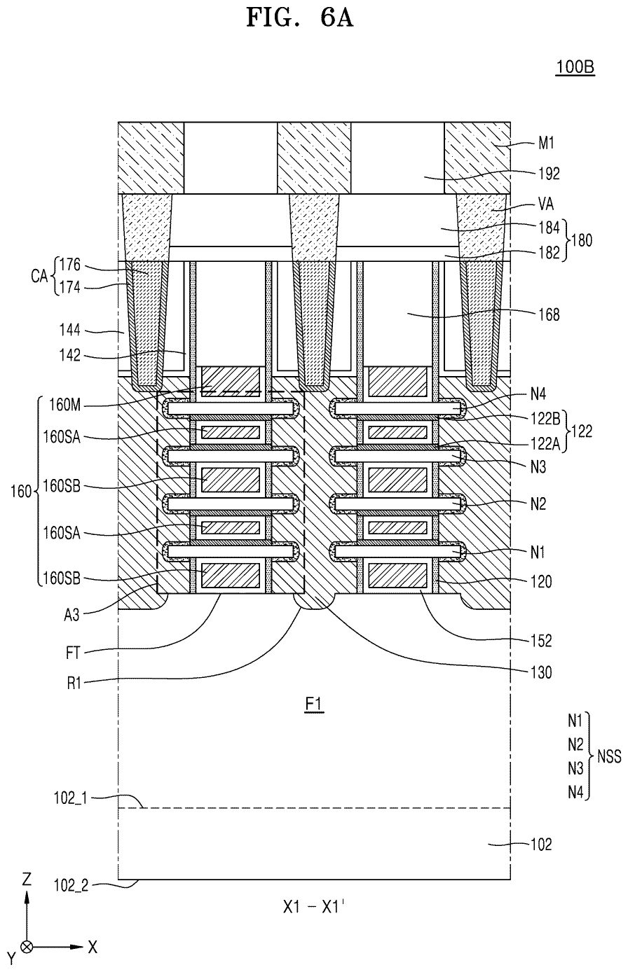

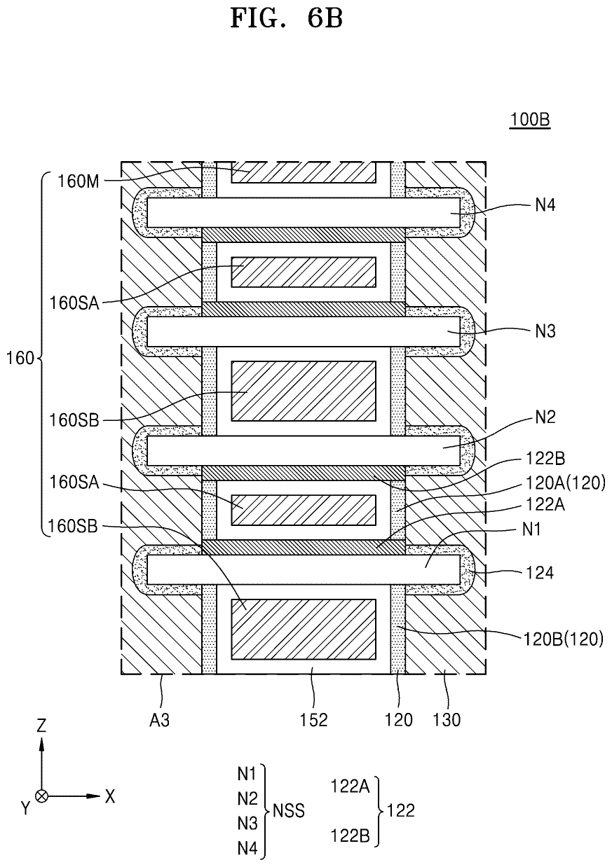

FIG. 6A is a cross-sectional view illustrating a partial configuration of an integrated circuit device 100B according to embodiments. FIG. 6B is an enlarged cross-sectional view of some components included in FIG. 6A. More specifically, FIG. 6B is an enlarged cross-sectional view of the third portion A3 of FIG. 6A. Anything not described below may be substantially identical to what is described above.

Referring to FIGS. 6A and 6B, the integrated circuit device 100B according to embodiments may include a plurality of channel barriers 124 each surrounding both lateral ends of each of the first to fourth channel layers N1, N2, N3, and N4 included in the nanosheet stack NSS. For example, each of the plurality of channel barriers 124 may be provided at both lateral ends of each of the first channel layer N1, the second channel layer N2, the third channel layer N3, and the fourth channel layer N4.

The plurality of channel barriers 124 may be disposed between the first to fourth channel layers N1, N2, N3, and N4 and the plurality of source/drain patterns 130. The first to fourth channel layers N1, N2, N3, and N4 may be spaced apart from the plurality of source/drain patterns 130, and the plurality of channel barriers 124 may be disposed between the first to fourth channel layers N1, N2, N3, and N4 and the plurality of source/drain patterns 130, respectively. In embodiments, the lateral ends of the first to fourth channel layers N1, N2, N3, and N4 may be completely surrounded by the plurality of channel barriers 124.

The plurality of channel barriers 124 may be in direct contact with the channel passivation layer 122 and may be in contact with the second spacer 120B. In other embodiments, the plurality of channel barriers 124 may be in contact with the channel passivation layer 122 and the adjacent first spacer 120A.

The plurality of channel barriers 124 may include a transition metal. Specifically, a transition metal included in the plurality of channel barriers 124 may be a group 4 transition metal. For example, the plurality of channel barriers 124 may include Ti, Zr, or Hf. However, the inventive concept is not limited thereto. In embodiments, the plurality of channel barriers 124 may include TMD.

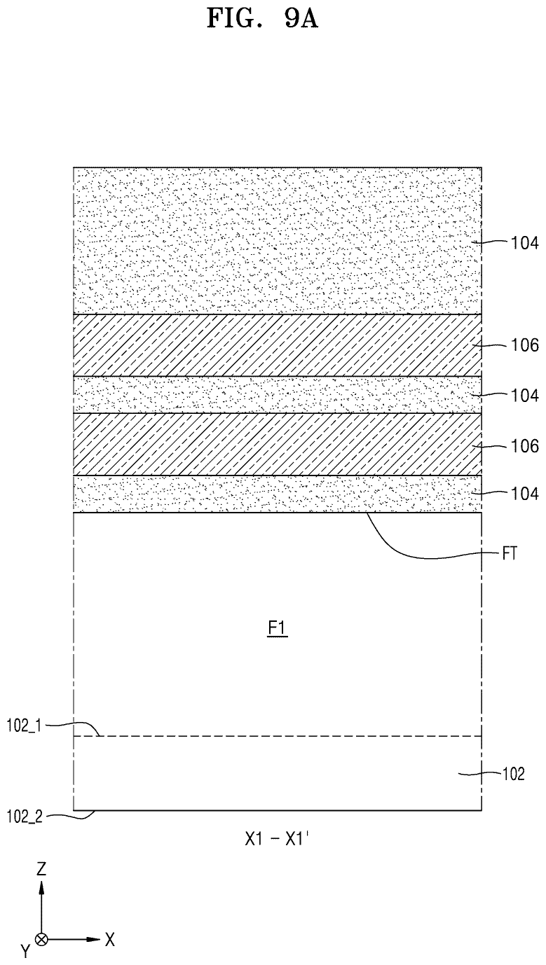

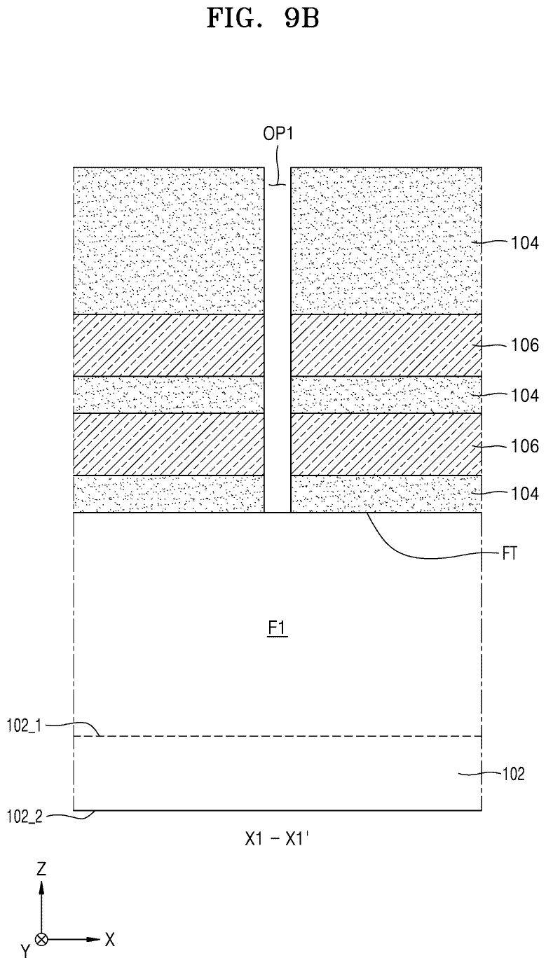

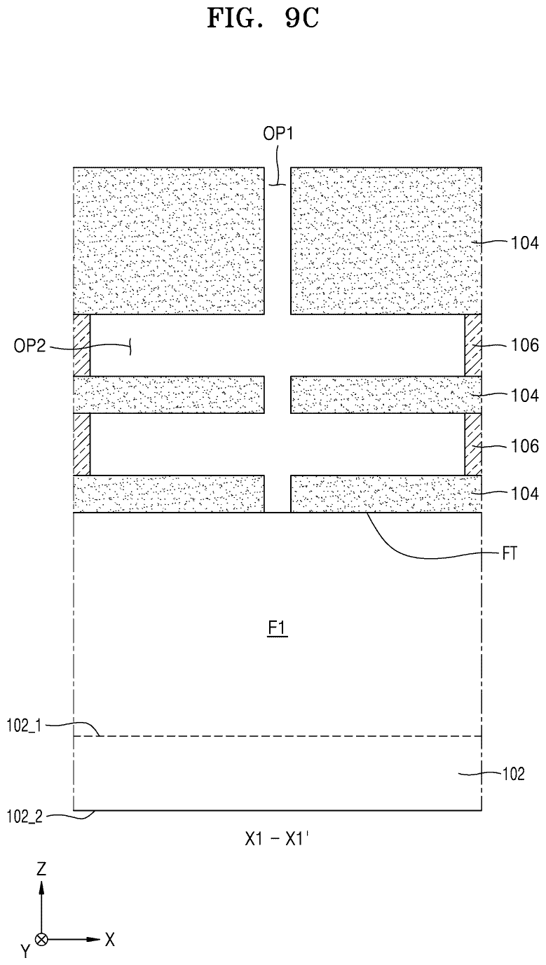

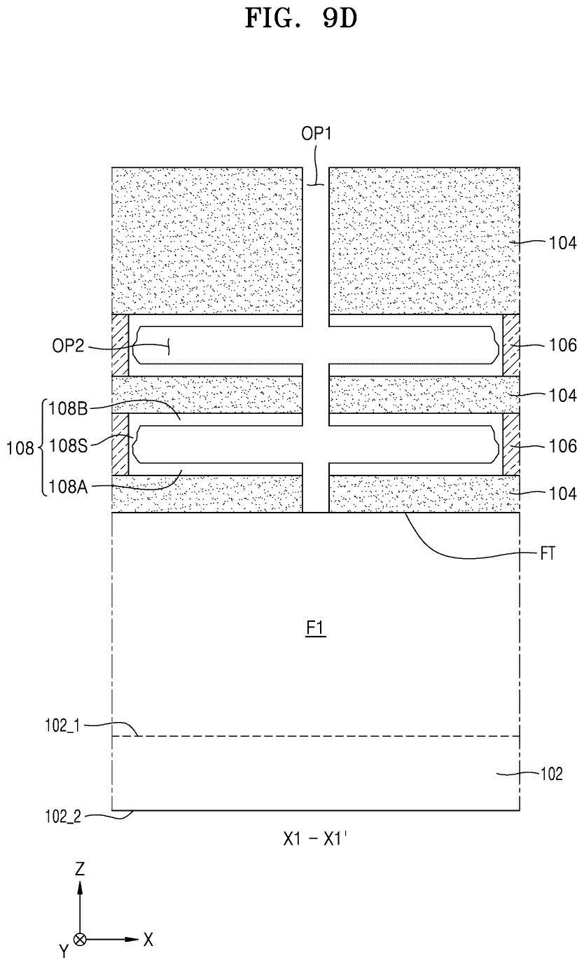

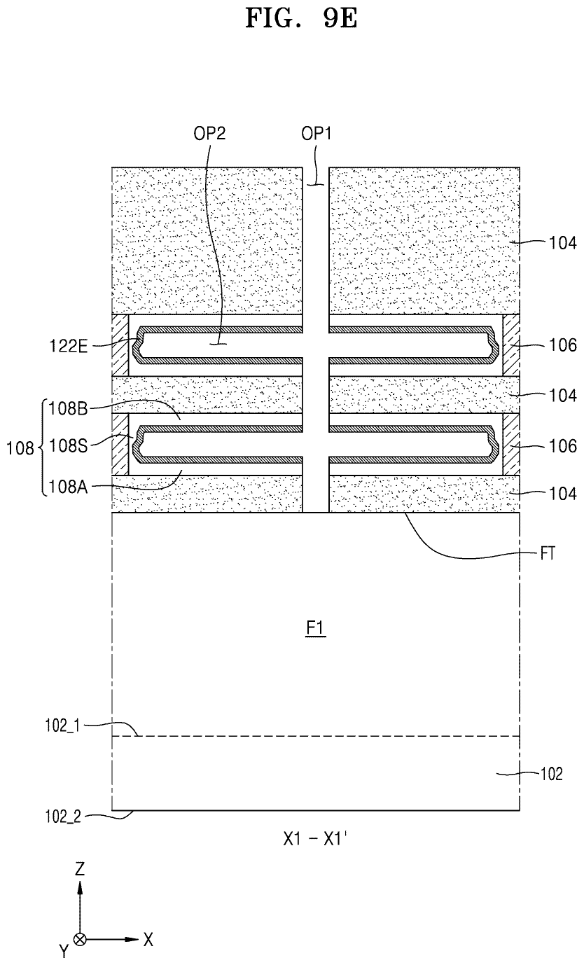

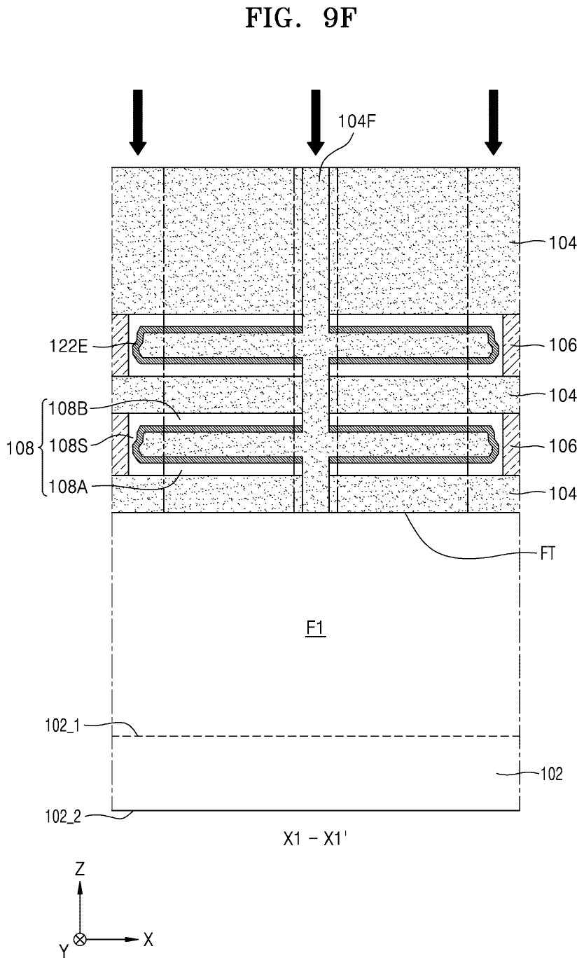

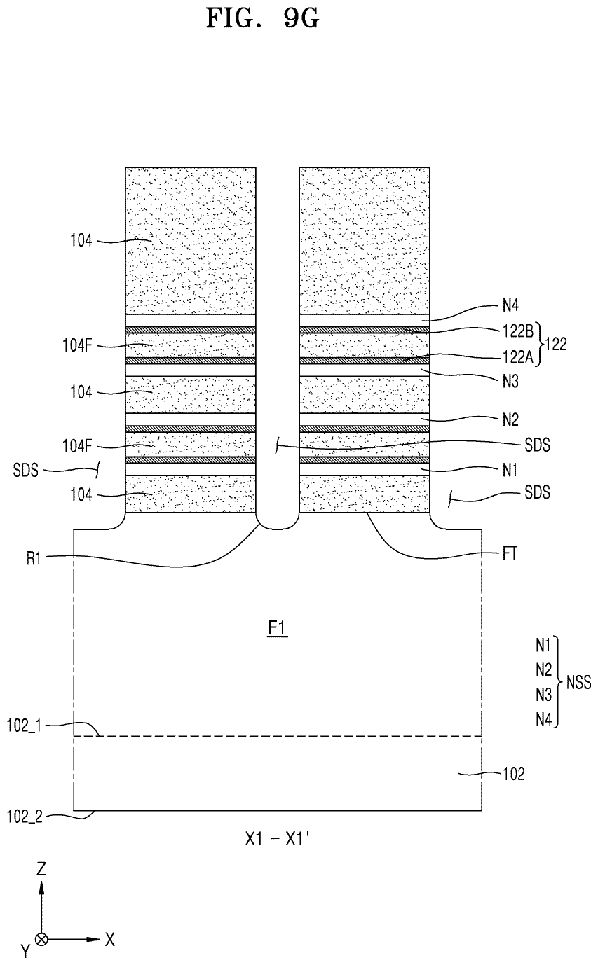

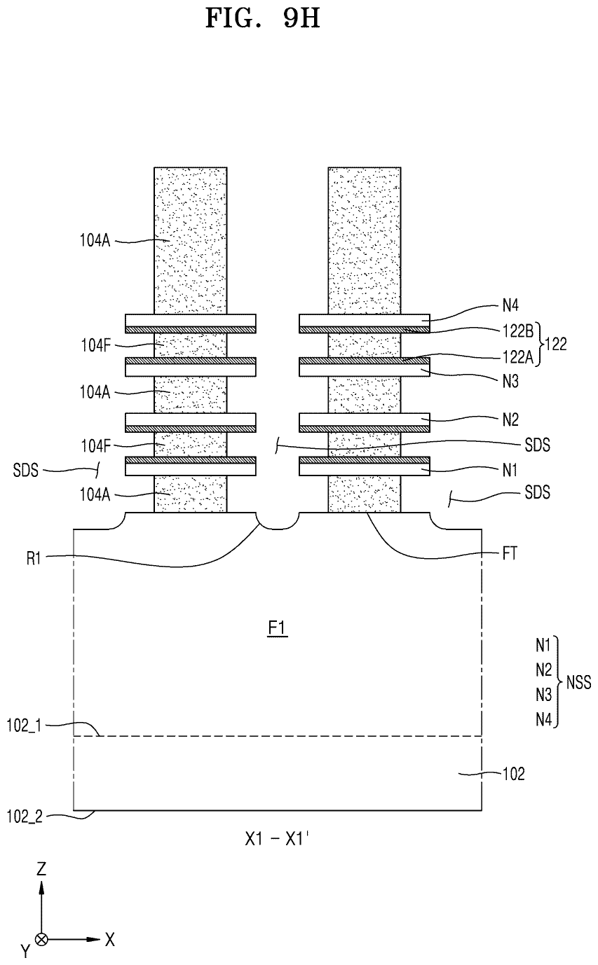

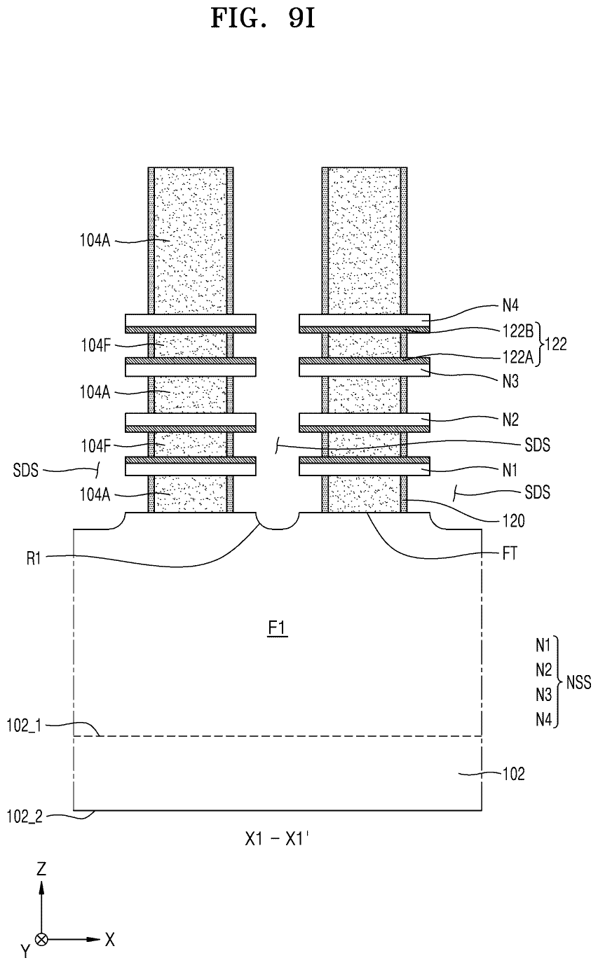

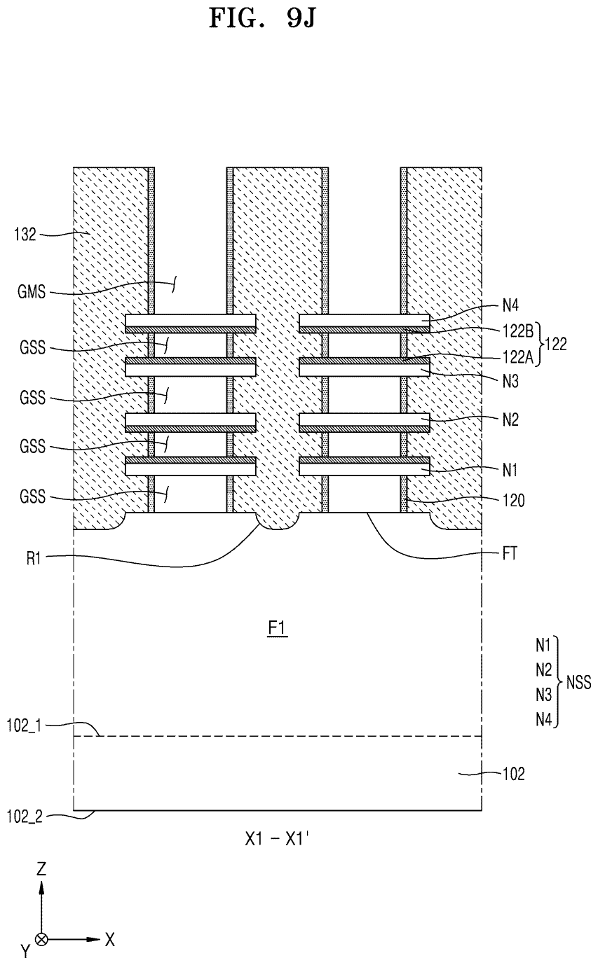

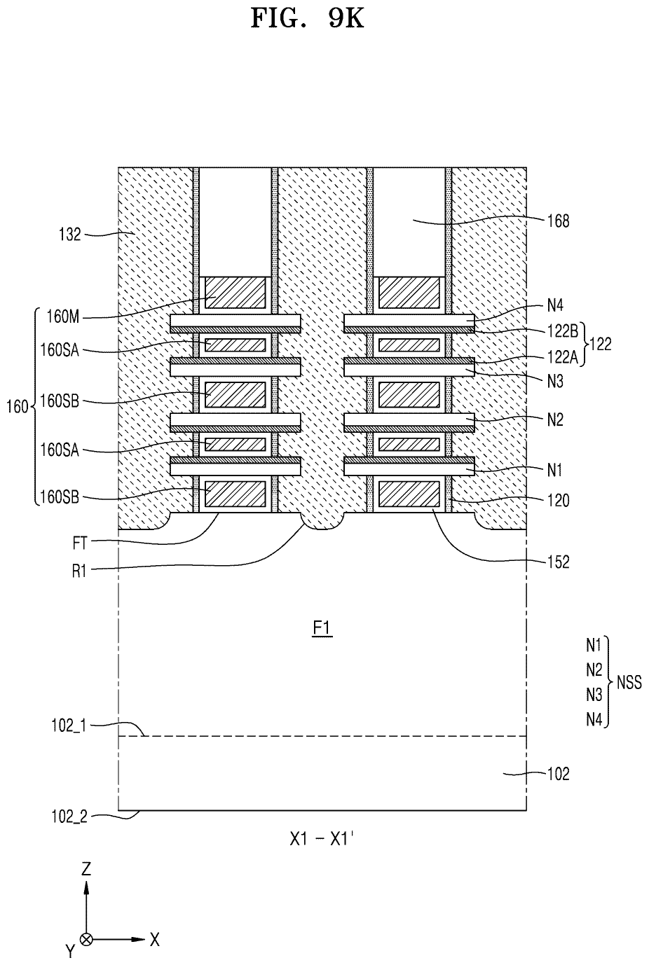

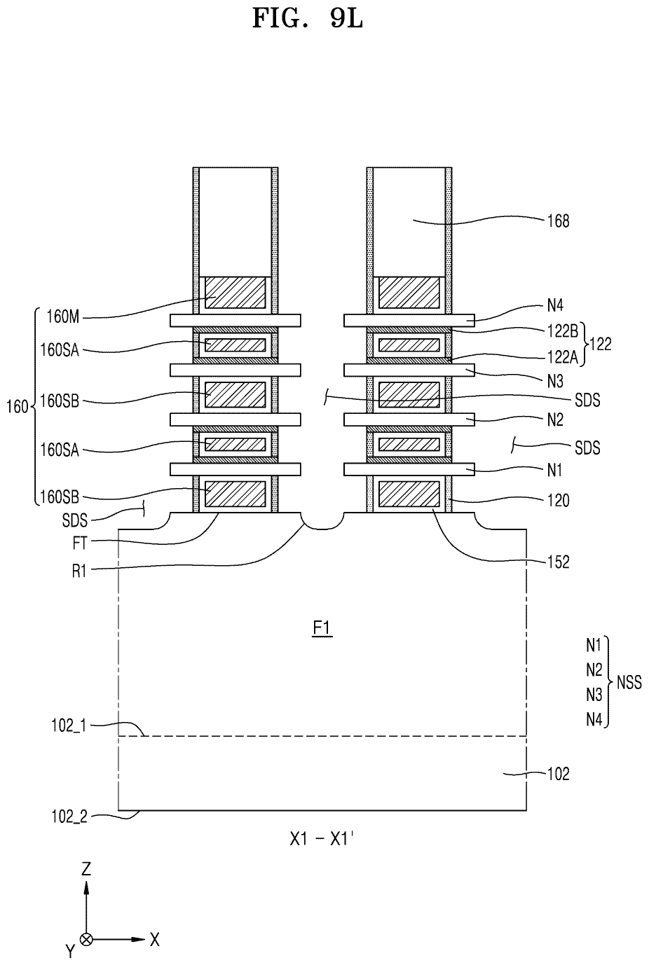

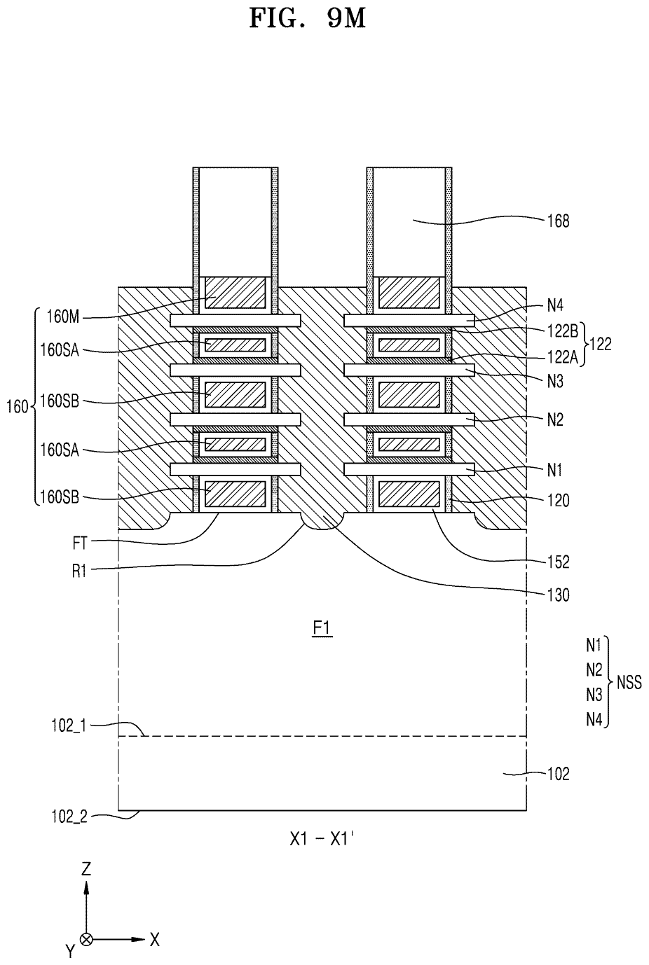

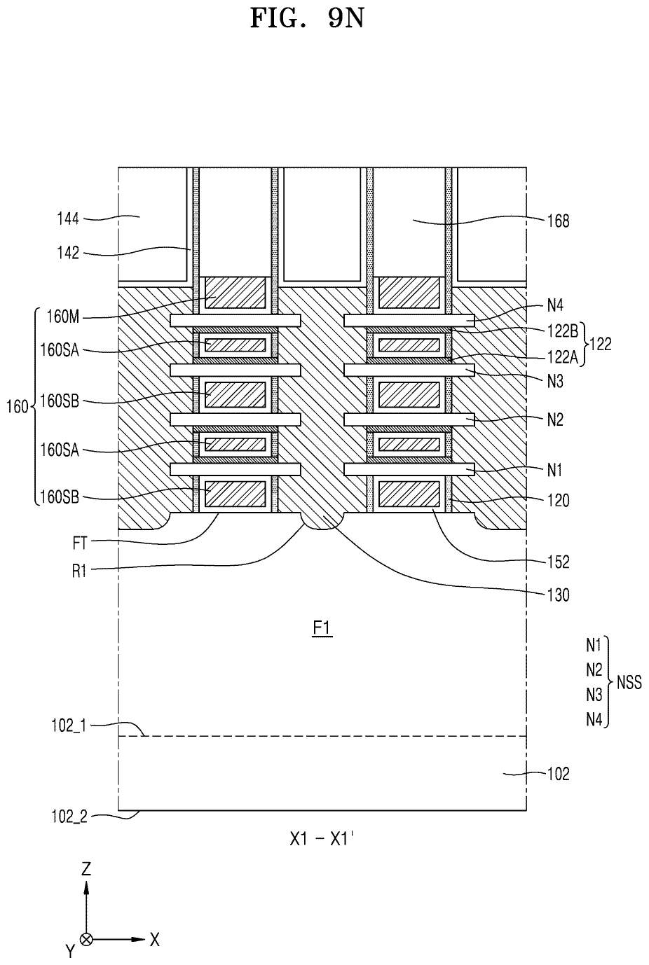

Through the plurality of channel barriers 124, after the first to fourth channel layers N1, N2, N3, and N4 are formed, the first to fourth channel layers N1, N2, N3, and N4 may be protected in the process. For example, in the process of forming the source/drain pattern 130 filling the source/drain region SDS described below in FIG. 9M, damage to the first to fourth channel layers N1, N2, N3, and N4 that may occur during the process of forming the source/drain pattern 130 through deposition may be prevented through the plurality of channel barriers 124.

For example, in the process of forming the source/drain pattern 130, deposition of a metal may be performed at a high temperature or in a plasma state. The first to fourth channel layers N1, N2, N3, and N4 including TMD exposed to such conditions may include S and/or selenium (Se), which may escape at high temperatures. Alternatively, surfaces of the first to fourth channel layers N1, N2, N3, and N4 may be oxidized or cause an unintended compounding reaction during the process of forming the source/drain pattern 130. The potential problems may be prevented through the plurality of channel barriers 124.

In addition, through the plurality of channel barriers 124, contact resistance between the first to fourth channel layers N1, N2, N3, and N4 and the source/drain pattern 130 may be reduced. For example, ohmic contact between the source/drain pattern 130 and the first to fourth channel layers N1, N2, N3, and N4 may be performed through the plurality of channel barriers 124. That is, through the plurality of channel barriers 124 of the integrated circuit device 100B according to embodiments, the first to fourth channel layers N1, N2, N3, and N4 may be protected, and at the same time, contact quality between the first to fourth channel layers N1, N2, N3, and N4 and the source/drain pattern 130 may be improved.

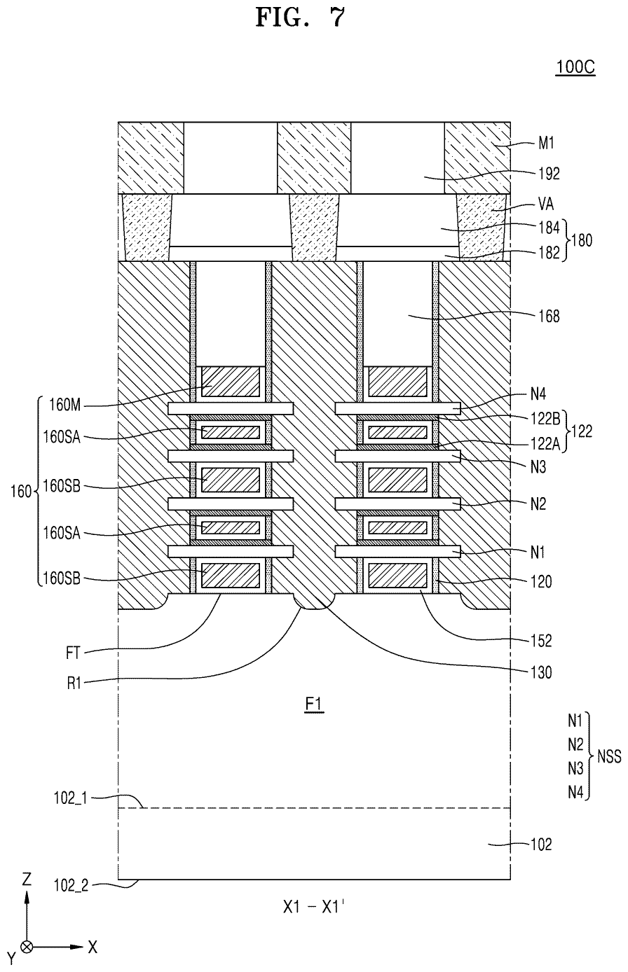

FIG. 7 is a cross-sectional view illustrating a partial configuration of an integrated circuit device 100C according to embodiments. Anything not described below may be substantially identical to what is described above.

Referring to FIG. 7, a source/drain pattern 130 constituting the integrated circuit device 100C according to embodiments may extend from a fin top surface FT and a recess R1 on a top surface of a substrate 102 to an etch stop layer 182. The source/drain pattern 130 may be in overall contact with sidewalls of two adjacent insulating spacers 120 facing each other with the source/drain pattern 130 therebetween. That is, unlike the integrated circuit device 100 described above, the integrated circuit device 100C of FIG. 7 may not include an insulating liner 142, an inter-gate insulating layer 144, and a plurality of source/drain contacts CA.

The source/drain pattern 130 may include metal and/or semi-metal, and a source/drain via contact VA may be in direct contact with a top surface of the source/drain pattern 130. The source/drain via contact VA may have a conductive barrier layer disposed on a surface thereof.

The source/drain pattern 130 may be in direct contact with the source/drain via contact VA so that the source/drain pattern 130 may be electrically connected to the source/drain via contact VA. Because the source/drain pattern 130 includes a metal and/or a semi-metal, contact resistance between the source/drain pattern 130 and the source/drain via contact VA may be reduced so that performance of the integrated circuit device 100C according to embodiments may be improved.

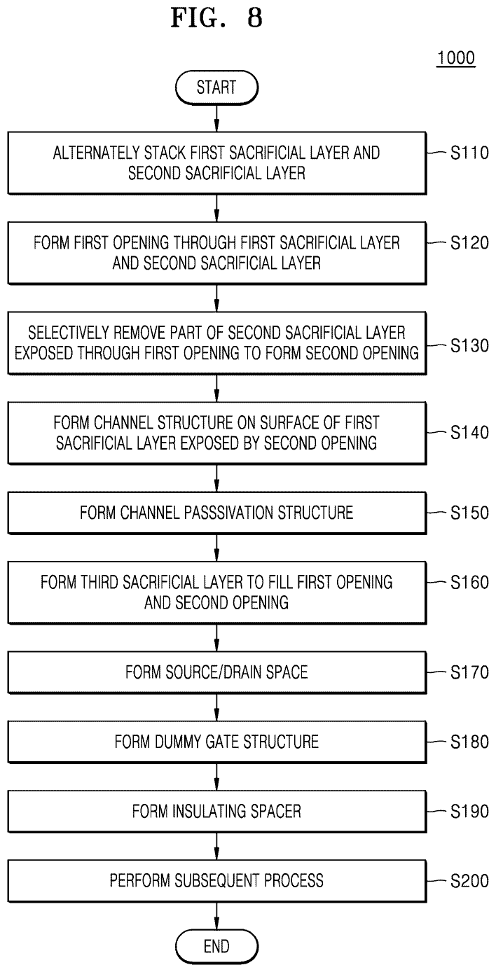

FIG. 8 is a flowchart illustrating an integrated circuit device manufacturing method 1000 according to embodiments. FIGS. 9A to 9N are views for sequentially describing an integrated circuit device manufacturing method 1000 according to embodiments. Anything not described below may be substantially identical to what is described above.

Referring to FIG. 8, description of a flowchart illustrating the integrated circuit device manufacturing method 1000 according to embodiments may be given specifically with reference to FIGS. 9A to 9N.

Referring to FIG. 9A, a plurality of first sacrificial layers 104 and a plurality of second sacrificial layers 106 may be alternately stacked by one layer on a substrate 102. The first sacrificial layer 104 stacked on the top may be formed to have a thickness in the vertical direction greater than the other first sacrificial layers 104, which may be for the formation of a main gate 160M and a capping insulation pattern 168 to be formed in a subsequent process.

In embodiments, the plurality of first sacrificial layers 104 and the plurality of second sacrificial layers 106 may include materials having different nucleation rates for TMD. In embodiments, the first sacrificial layer 104 may be directly disposed on a top surface of the substrate 102, and the plurality of first sacrificial layers 104 alternately stacked with the plurality of second sacrificial layers 106 may include at least one material among aluminum oxide (AlOₓ), zirconium oxide (ZrOₓ), titanium oxide (TiOₓ), and aluminum oxide (AlOₓ). The plurality of second sacrificial layers 106 disposed on the first sacrificial layer 104 directly disposed on the substrate 102 and alternately stacked with the plurality of first sacrificial layers 104 may include at least one material among silicon nitride (SiNₓ) and silicon oxide (SiOₓ).

For example, when molybdenum disulfide (MoS₂) is used as a material forming the first to fourth channel layers N1, N2, N3, and N4 to be described below, a nucleation rate may be high on the plurality of first sacrificial layers 104 including AlOₓ and may be low on the plurality of second sacrificial layers 106 including SiNₓ or SiOₓ. Accordingly, selective area growth is performed so that the first to fourth channel layers N1, N2, N3, and N4 including single-crystal TMD may be formed in a shape including a flat plate of a uniform thickness, which will be specifically described with reference to FIG. 9D.

Referring to FIG. 9B, a process of removing the plurality of first sacrificial layers 104 and the plurality of second sacrificial layers 106 in the vertical direction to form a first opening OP1 reaching an active region F1 may be performed. For example, the plurality of first sacrificial layers 104 and the plurality of second sacrificial layers 106 may be sequentially removed from the top by using reactive ion etching (RIE) or inductively coupled plasma (ICP) etching to form the first opening OP1. Although it is illustrated in FIG. 9B that the first opening OP1 is formed in only one position, in reality, the first opening OP1 may be repeatedly formed at a certain interval in the horizontal direction.

Referring to FIG. 9C, cross-sections of the plurality of second sacrificial layers 106 exposed through the first opening OP1 may be selectively removed. For example, by using a wet etchant such as HF series or buffered oxide etchant (BOE), the plurality of first sacrificial layers 104 may not be removed, and only the plurality of second sacrificial layers 106 may be removed. Accordingly, the cross-sections of the plurality of second sacrificial layers 106 exposed through the first opening OP1 may be selectively etched in the horizontal direction. Parts of the plurality of second sacrificial layers 106 may be removed so that a plurality of second openings OP2 may be formed among the plurality of first sacrificial layers 104. Because the first to fourth channel layers N1, N2, N3, and N4 and the channel passivation layer 122 are formed in the plurality of second openings OP2 by the subsequent process described below, a degree of etching of the plurality of second sacrificial layers 106 needs to be appropriately controlled.

Referring to FIG. 9D, a channel structure 108 may be formed in the second opening OP2 formed in a previous process. In embodiments, the channel structure 108 may include single-crystal TMD. The channel structure 108 may be formed through chemical vapor deposition (CVD), metal-organic chemical vapor deposition (MOCVD), or atomic layer deposition (ALD).

For example, deposition of TMD formed through the above-described deposition process has a high nucleation rate on the plurality of first sacrificial layers 104 and a low nucleation rate on the plurality of second sacrificial layers 106, so that the channel structure 108 may be grown at a relatively high growth rate on the plurality of first sacrificial layers 104.

TMD has a plate-like crystal structure so that it is more likely that bonding occur in the plane. Because the nucleation rate is high on the plurality of first sacrificial layers 104, nuclei of TMD are formed on the plurality of first sacrificial layers 104 at the beginning of the deposition process, and then a TMD layer may be formed planarly on the plurality of first sacrificial layers 104.

Due to the formation characteristics of such TMD, as illustrated in FIG. 9D, a first channel structure 108A is formed on a top surface of the first sacrificial layer 104 in the second opening OP2, and a second channel structure 108B is formed on a bottom surface of the first sacrificial layer 104 to face the first channel structure 108A, whereas no or little formation of TMD may occur on the side surfaces of the plurality of first sacrificial layers 104 introduced into the first opening OP1.

In embodiments, a relatively small amount of third channel structure 108S may be formed on the sidewall of the second sacrificial layer 106 compared to the first channel structure 108A or the second channel structure 108B, as illustrated in FIG. 9D. In this case, a first channel structure 108A, a second channel structure 108B, and a third channel structure 108S may be formed along the first sacrificial layer 104 and the second sacrificial layer 106 exposed to the second opening OP2.

In other embodiments, a channel structure may not be formed on a sidewall of the second sacrificial layer 106 exposed to the second opening OP2. In some embodiments, a TMD layer may be formed on the first sacrificial layer 104 stacked on the top. The TMD layer may be removed by performing an additional process.

Referring to FIG. 9E, a channel passivation structure 122E may be formed in the plurality of channel structures 108 formed in the second opening OP2. The channel passivation structure 122E may be formed with a generally uniform thickness on surfaces exposed toward the second opening OP2 of the plurality of channel structures 108. The channel passivation structure 122E may be formed by deposition or immersion. However, the inventive concept is not limited thereto.

Here, the channel passivation structure 122E may include thiol or S, and may also include TFSI. In embodiments, the channel passivation structure 122E may include 3-octanethiol, ethanethiol, and diphenyl sulfide.

Referring to FIG. 9F, a third sacrificial layer 104F may be formed to fill the first opening OP1 and the plurality of second openings OP2. The third sacrificial layer 104F may include the same material as the first sacrificial layer 104. However, the inventive concept is not limited thereto. Along the dashed lines illustrated in FIG. 9F, part of the structure of FIG. 9F may be removed in a subsequent process. In embodiments, chemical-mechanical polishing (CMP) may be performed on the uppermost surface exposed to the outside as needed. The process structure of FIG. 9F may be referred to as a stacked structure in the current specification.

Referring to FIG. 9G, part of the structure of FIG. 9F may be removed to form a plurality of source/drain spaces SDS. In embodiments, the second sacrificial layer 106, part of the first channel structure 108A, part of the second channel structure 108B, the third channel structure 108S, part of the channel passivation structure 122E formed on the third channel structure 108S may be removed, and the third sacrificial layer 104F and part of the plurality of first sacrificial layers 104 adjacent thereto, part of the first channel structure 108A, part of the second channel structure 108B, and part of the channel passivation structure 122E may be removed.

The plurality of source/drain spaces SDS may be formed by dry etching, and during the formation process, part of the active region F1 may be etched to form a plurality of recesses R1. A vertical level of the lowermost surface of each of the plurality of recesses R1 may be lower than a vertical level of the fin top surface FT of the active region F1. However, the formation of the plurality of source/drain spaces SDS is not limited to dry etching.

Due to the formation of the plurality of source/drain spaces SDS, a structure may be formed in which the plurality of first sacrificial layers 104, the first to fourth channel layers N1, N2, N3, and N4, the channel passivation layer 122, and a plurality of third sacrificial layers 104F having substantially the same planar area are stacked in the same order as in FIG. 9G.

In the method 1000 of manufacturing an integrated circuit device according to embodiments, an even number of channel layers included in the nanosheet stack NSS may be formed due to the above-described process, which is, in particular, a result of forming the plurality of channel structures 108 serving as the basis for the first to fourth channel layers N1, N2, N3, and N4 on the plane of the first sacrificial layer 104 exposed to the second opening OP2, as illustrated in FIG. 9D. In addition, as illustrated in FIG. 9D, the plurality of channel structures 108 serving as a basis for the first to fourth channel layers N1, N2, N3, and N4 of the integrated circuit device 100 are formed by a single recovery process. Accordingly, the thickness of each of the first to fourth channel layers N1, N2, N3, and N4 formed through a subsequent process is more uniform than that of integrated circuit devices manufactured by sequentially stacking the integrated circuit devices in a conventional manner, and the first to fourth channel layers N1, N2, N3, and N4 may be manufactured with a consistent level of quality.

Referring to FIG. 9H, part of each of a plurality of first sacrificial layers 104A and the plurality of third sacrificial layers 104F exposed to each of the plurality of source/drain spaces SDS is removed so that the plurality of source/drain spaces SDS may be extended laterally. A structure in which the plurality of source/drain spaces SDS are extended laterally, and the plurality of first sacrificial layers 104A and the plurality of third sacrificial layers 104F are partially removed may be referred to as a dummy gate structure.

Referring to FIG. 9I, an insulating spacer 120 may be formed. In embodiments, the insulating spacer 120 may be formed on sidewalls of the plurality of first sacrificial layers 104A and sidewalls of the plurality of third sacrificial layers 104F exposed to each of the plurality of source/drain spaces SDS. The first to fourth channel layers N1, N2, N3, and N4 and the channel passivation layer 122 may protrude laterally from the insulating spacer 120.

The insulating spacer 120 may cover sidewalls in the first horizontal direction of the plurality of first sacrificial layers 104A and sidewalls in the first horizontal direction of the plurality of third sacrificial layers 104F. A pair of insulating spacers 120 may be formed on the sidewalls of the plurality of first sacrificial layers 104A and the plurality of third sacrificial layers 104F, with the plurality of first sacrificial layers 104A and the plurality of third sacrificial layers 104F stacked therebetween. The insulating spacer 120 may include silicon nitride, silicon oxide, SiCN, SiBN, SiON, SiOCN, SiBCN, SiOC, or a combination thereof.

Referring to FIG. 9J, an insulating layer 132 may be formed to fill a plurality of active region recesses R1 and a plurality of source/drain spaces SDS between mutually facing insulating spacers 120. The insulating layer 132 may cover the sidewalls of the plurality of insulating spacers 120, the sidewalls of the first to fourth channel layers N1, N2, N3, and N4, and the sidewall of the channel passivation layer 122. The insulating layer 132 may include silicon oxide (SiO₂). However, the inventive concept is not limited thereto.

After forming the insulating layer 132, a plurality of dummy gate structures provided among the insulating spacers 120 may be removed. A sub-gate space GSS and a main gate space GMS defined by a space between the insulating spacers 120, the fin top surface FT, and the recess R1 may be formed. The plurality of dummy gate structures may include the plurality of first sacrificial layers 104A and the plurality of third sacrificial layers 104F. In some embodiments, the main gate space GMS may be formed first, followed by the sub gate space GSS.

Referring to FIG. 9K, a high-k dielectric layer may be formed on the process result of FIG. 9J to form a gate dielectric layer 152 covering the first to fourth channel layers N1, N2, N3, and N4, the exposed surfaces of the plurality of active regions F1, and the exposed surfaces of the channel passivation layer 122. After a conductive layer is formed to fill the sub-gate space GSS and the main gate space GMS remaining after the gate dielectric layer 152 is formed, the conductive layer may be etched back so that part of the upper side of the main gate space GMS becomes empty again.

As a result, a gate line 160 covering the gate dielectric layer 152 may be formed. The gate line 160 may include a metal, metal nitride, metal carbide, or a combination thereof. An ALD process or a CVD process may be used to form the gate line 160.

Thereafter, a capping insulation pattern 168 may be formed to fill the space of the upper portion of the main gate portion 160M and the insulating spacer 120 on the gate line 160.

Referring to FIG. 9L, the insulating layer 132 may be removed to form the source/drain space SDS. In the process of removing the insulating layer 132, part of both ends of the channel passivation layer 122 protruding laterally from the insulating spacer 120 may be removed. As a result, a top or bottom surface of each of the first to fourth channel layers N1, N2, N3, and N4 may be exposed to the source/drain space SDS.

Referring to FIG. 9M, the plurality of source/drain patterns 130 may be formed to occupy at least part of the source/drain space SDS. The plurality of source/drain patterns 130 may include a metal or a semi-metal and may be formed through deposition. Here, as the deposition process, physical vapor deposition (PVD), CVD, or ALD may be used. In some embodiments, heat treatment may be performed to provide ohmic contact with other components of the plurality of source/drain patterns 130.

Referring to FIG. 9N, after forming the insulating liner 142 covering the plurality of source/drain patterns 130, and forming the inter-gate insulating layer 144 on the insulating liner 142, a process of planarizing the insulating liner 142 and the inter-gate insulating layer 144 may be performed.

Referring again to FIGS. 2A, 2B, 3, and 4, a plurality of source/drain contact holes (not shown) may be formed to expose the plurality of source/drain patterns 130 through an insulating structure including the insulating liner 142 and the inter-gate insulating layer 144. A partial region of the plurality of source/drain patterns 130 may be removed through the source/drain contact holes (not shown) by an anisotropic etching process so that the plurality of source/drain contact holes (not shown) may extend longer toward the substrate 102.

Thereafter, the source/drain contact CA including the conductive barrier layer 174 and the contact plug 176 formed in the space of the plurality of source/drain contact holes (not shown) and in contact with part of the exposed source/drain pattern 130 may be formed.

Thereafter, the etch stop layer 182 and the interlayer insulating layer 184 covering top surfaces of the inter-gate insulating layer 144, the plurality of source/drain contacts CA, and the plurality of capping insulation patterns 168 may be sequentially formed to form the upper insulating structure 180, and the plurality of source/drain via contacts VA connected to the plurality of source/drain contacts CA may be formed through the upper insulating structure 180 in the vertical direction.

Thereafter, the upper insulating layer 192 covering top surfaces of the upper insulating structure 180 and the plurality of source/drain via contacts VA may be formed, and the plurality of upper wiring layers M1 connected to the plurality of source/drain via contacts VA may be formed through the upper insulating layer 192 in the vertical direction.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a plurality of channel layers extending in a first horizontal direction and including a first channel layer and a second channel layer;
a gate line extending in a second horizontal direction intersecting the first horizontal direction, and surrounding the plurality of channel layers, the gate line including a first sub-gate arranged between the first channel layer and the second channel layer;
a source/drain pattern arranged on a sidewall of the gate line and connected to the plurality of channel layers; and
a channel passivation layer including a first passivation layer and a second passivation layer, wherein the first passivation layer is disposed between the first sub-gate and the first channel layer, and the second passivation layer is arranged between the first sub-gate and the second channel layer,
wherein the plurality of channel layers protrude in the first horizontal direction from the sidewall of the gate line, and
wherein the plurality of channel layers comprise transition metal dichalcogenides (TMD).

2. The integrated circuit device of claim 1,
wherein a thickness in a third direction of each of the plurality of channel layers is substantially the same,
wherein a distance between adjacent channel layers of the plurality of channel layers is substantially the same, and
wherein the third direction is perpendicular to the first horizontal direction and the second horizontal direction.

3. The integrated circuit device of claim 2,
wherein the gate line further comprises a second sub-gate,
wherein the second sub-gate is positioned on an opposite side to the first sub-gate with respect to the first channel layer, and
wherein a thickness in the third direction of the second sub-gate is greater than a thickness in the third direction of the first sub-gate.

4. The integrated circuit device of claim 1, wherein the plurality of channel layers comprise an even number of channel layers.

5. The integrated circuit device of claim 1, wherein the source/drain pattern comprises a metal, a semi-metal, a metal oxide, or a combination thereof, and
wherein the channel passivation layer comprises at least one of thiol or sulfur(S).

6. The integrated circuit device of claim 1, wherein the plurality of channel layers have a single-crystal structure.

7. The integrated circuit device of claim 1,
wherein the first passivation layer is in direct contact with a top surface of the first channel layer, and
wherein the second passivation layer is in direct contact with a bottom surface of the second channel layer.

8. The integrated circuit device of claim 1,
wherein one end of the first passivation layer and one end of the second passivation layer are in contact with the source/drain pattern.

9. The integrated circuit device of claim 1, wherein the channel passivation layer is alternately arranged between adjacent channel layers of the plurality of channel layers.

10. The integrated circuit device of claim 1,
wherein the gate line further comprises a second sub-gate,
wherein the first channel layer is disposed between the first sub-gate and the second sub-gate, and
wherein a channel passivation layer is not disposed between the first channel layer and the second sub-gate.

11. The integrated circuit device of claim 1, further comprising
an insulating spacer arranged between a sidewall of the gate line and the source/drain pattern,
wherein the insulating spacer comprises a first spacer arranged between the first channel layer and the second channel layer, wherein a first passivation layer is arranged between the first spacer and the first channel layer.

12. The integrated circuit device of claim 11, wherein the first spacer is spaced apart from the first channel layer and the second channel layer.

13. The integrated circuit device of claim 11,
wherein a first surface of the first spacer faces the first sub-gate, and a second surface of the first spacer is in contact with the source/drain pattern,
wherein one end of the first passivation layer extends to a surface formed by the second surface of the first spacer on a top surface of the first channel layer, and
wherein the second surface of the first spacer is an opposite surface to the first surface of the first spacer.

14. The integrated circuit device of claim 11, further comprising:
an insulating spacer disposed between the sidewall of the gate line and the source/drain pattern; and
a capping insulation pattern disposed on a main gate on a side of the insulating spacer,
wherein the gate line comprises the main gate disposed above the plurality of channel layers, and
wherein the insulating spacer integrally extends on a sidewall of the first sub-gate, a sidewall of the main gate, and a sidewall of the capping insulation pattern.

15. An integrated circuit device comprising:
a plurality of channel layers extending in a first horizontal direction and including a first channel layer and a second channel layer;
a gate line extending in a second horizontal direction intersecting the first horizontal direction, and surrounding the plurality of channel layers, wherein the gate line includes a first sub-gate arranged between the first channel layer and the second channel layer, and a second sub-gate disposed on an opposite side to the first sub-gate with respect to the first channel layer;
a source/drain pattern disposed on a sidewall of the gate line and connected to the plurality of channel layers;
a channel passivation layer including a first passivation layer and a second passivation layer, wherein the first passivation layer is disposed between the first sub-gate and the first channel layer, and the second passivation layer is arranged between the first sub-gate and the second channel layer;
an insulating spacer disposed between a sidewall of the gate line and the source/drain pattern; and
a gate dielectric layer surrounding the first sub-gate,
wherein the plurality of channel layers protrude in the first horizontal direction from the insulating spacer,
wherein a channel passivation layer is not disposed between the first channel layer and the second sub-gate,
wherein the first passivation layer is disposed between the gate dielectric layer and the first channel layer and the gate dielectric layer is in direct contact with the first passivation layer, and
wherein the plurality of channel layers comprise transition metal dichalcogenides (TMD).

16. The integrated circuit device of claim 15,
wherein the plurality of channel layers comprise an even number of channel layers,
wherein a thickness in a third direction of each of the plurality of channel layers is substantially the same, and the third direction is perpendicular to the first horizontal direction and the second horizontal direction,
wherein the plurality of channel layers have a single-crystal structure, and
wherein the source/drain pattern comprises a metal, a semi-metal, a metal oxide, or a combination thereof.

17. The integrated circuit device of claim 15,
wherein the insulating spacer comprises a first spacer disposed between the first channel layer and the second channel layer, and a first passivation layer is disposed between the first spacer and the first channel layer,
wherein the first spacer is spaced apart from the first channel layer and the second channel layer, a first surface of the first spacer faces the first sub-gate, a second surface of the first spacer is in contact with the source/drain pattern, and the second surface of the first spacer is an opposite surface to the first surface of the first spacer, and
wherein one end of the first passivation layer extends to the second surface of the first spacer.

18. The integrated circuit device of claim 17,
wherein an end of each of the plurality of channel layers is surrounded by a channel barrier,
wherein the end of each of the plurality of channel layers is spaced apart from the source/drain pattern by the channel barrier,
wherein the channel barrier comprises gold (Au), palladium (Pd), and platinum (Pt),
wherein the channel barrier is in contact with the channel passivation layer, and
wherein the channel barrier is selectively formed at the end of each of the plurality of channel layers.

19. The integrated circuit device of claim 15,
wherein a thickness in the third direction of each of the plurality of channel layers is in a range of 0.3 nanometers (nm) to 2.0 nm,
wherein a thickness in the third direction of the channel passivation layer is in a range of 0.1 nm to 0.5 nm, and
wherein the third direction is perpendicular to the first horizontal direction and the second horizontal direction.

20. An integrated circuit device comprising:
a plurality of channel layers extending in a first horizontal direction and including a first channel layer and a second channel layer;
a gate line extending in a second horizontal direction intersecting the first horizontal direction, and surrounding the plurality of channel layers, wherein the gate line includes a first sub-gate disposed between the first channel layer and the second channel layer, and a second sub-gate disposed on an opposite side to the first sub-gate with respect to the first channel layer;
a source/drain pattern disposed on a sidewall of the gate line and connected to the plurality of channel layers;
a channel passivation layer including a first passivation layer and a second passivation layer, wherein the first passivation layer is disposed between the first sub-gate and the first channel layer, and the second passivation layer is disposed between the first sub-gate and the second channel layer;
an insulating spacer disposed between a sidewall of the gate line and the source/drain pattern; and
a gate dielectric layer surrounding the first sub-gate,
wherein the plurality of channel layers protrude in the first horizontal direction from the insulating spacer,
wherein a channel passivation layer is not disposed between the first channel layer and the second sub-gate,
wherein the first passivation layer is disposed between the gate dielectric layer and the first channel layer and the gate dielectric layer is in direct contact with the first passivation layer,
wherein the plurality of channel layers comprise transition metal dichalcogenides (TMD),
wherein the plurality of channel layers comprise an even number of channel layers,
wherein a thickness in a third direction of each of the plurality of channel layers is substantially the same, and the third direction is perpendicular to the first horizontal direction and the second horizontal direction,
wherein the plurality of channel layers have a single-crystal structure,
wherein the source/drain pattern comprises a metal, a semi-metal, a metal oxide, or a combination thereof,
wherein the channel passivation layer comprises at least one of thiol or S,
wherein the channel passivation layer comprises trifluoromethanesulfonylimide (TFSI), and
wherein a thickness in the third direction of each of the plurality of channel layers is in a range of 0.3 nanometers (nm) to 2.0 nm, and a thickness in the third direction of the channel passivation layer is in a range of 0.1 nm to 0.5 nm.
